(19) United States
(12) Patent Application Publication
(10) Pub. No.: US 2026/0043857 A1
(43) Pub. Date: Feb. 12, 2026

(54) BATTERY PACK AND DIAGNOSIS METHOD

(71) Applicant: MURATA MANUFACTURING CO., LTD., Kyoto (JP)

(72) Inventors: Hiroto KANOMATA, Kyoto (JP); Christopher Stephen Lawrence D'SOUZA, Kyoto (JP)

(21) Appl. No.: 19/264,141

(22) Filed: Jul. 9, 2025

(30) Foreign Application Priority Data
Aug. 9, 2024 (JP) 2024-134432

(51) Int. Cl. G01R 31/3835; G01R 31/396; H01M 10/42; H01M 50/51

(52) U.S. Cl. CPC G01R 31/3835; G01R 31/396; H01M 10/4207; H01M 10/4264; H01M 50/51

(57) ABSTRACT

A battery pack includes a storage battery, multiple switches, a voltage detection circuit, and a diagnosis circuit. The storage battery includes multiple battery cells coupled in series. The switches correspond to the respective battery cells and are each provided in a first parallel path of corresponding one of the battery cells. The voltage detection circuit is configured to detect respective voltages across the switches, as multiple cell voltages corresponding to the respective battery cells. The diagnosis circuit is configured to put one or more of the switches into an on state in a predetermined period, and configured to perform a diagnosis process based on a detection result of the voltage detection circuit before the predetermined period and a detection result of the voltage detection circuit after the predetermined period.

### CROSS-REFERENCE TO RELATED APPLICATIONS

The present application claims priority from Japanese Patent Application No. 2024-134432 filed on Aug. 9, 2024, the entire contents of which are hereby incorporated by reference.

### BACKGROUND

The present disclosure relates to a battery pack including a storage battery, and to a diagnosis method for the battery pack.

In an apparatus including a storage battery, a diagnosis process of diagnosing whether a malfunction has occurred is often performed. For example, a cell balance control apparatus is disclosed as configured to detect a disconnection of wiring for cell voltage detection.

### SUMMARY

The present disclosure relates to a battery pack including a storage battery, and to a diagnosis method for the battery pack.

A battery pack according to one embodiment of the present disclosure includes a storage battery, multiple switches, a voltage detection circuit, and a diagnosis circuit. The storage battery includes multiple battery cells coupled in series. The switches correspond to the respective battery cells and are each provided in a first parallel path of corresponding one of the battery cells. The voltage detection circuit is configured to detect respective voltages across the switches, as multiple cell voltages corresponding to the respective battery cells. The diagnosis circuit is configured to put one or more of the switches into an on state in a predetermined period, and configured to perform a diagnosis process based on a detection result of the voltage detection circuit before the predetermined period and a detection result of the voltage detection circuit after the predetermined period.

A diagnosis method according to one embodiment of the present disclosure includes: detecting, in a battery pack including multiple battery cells and multiple switches, respective voltages across the switches, as multiple first cell voltages corresponding to the respective battery cells, the battery cells being coupled in series, the switches corresponding to the respective battery cells and each being provided in a first parallel path of corresponding one of the battery cells; putting one or more of the switches into an on state in a predetermined period; detecting respective voltages across the switches after the predetermined period, as multiple second cell voltages corresponding to the respective battery cells; and performing a diagnosis process based on the first cell voltages and the second cell voltages.

### BRIEF DESCRIPTION OF THE DRAWINGS

The accompanying drawings are included to provide a further understanding of the present disclosure and are incorporated in and constitute a part of this specification. The drawings illustrate example embodiments and, together with the specification, serve to explain the principles of the present disclosure.

FIG. 1 is a block diagram illustrating a configuration example of a battery pack according to one example embodiment of the present disclosure.

FIG. 2A is a flowchart illustrating an operation example of the battery pack illustrated in FIG. 1.

FIG. 2B is another flowchart illustrating the operation example of the battery pack illustrated in FIG. 1.

FIG. 3A is a flowchart illustrating an operation example of voltage measurement illustrated in FIG. 2A.

FIG. 3B is another flowchart illustrating the operation example of the voltage measurement illustrated in FIG. 2A.

FIG. 4A is a flowchart illustrating an operation example of a disconnection determination process illustrated in FIG. 2A.

FIG. 4B is another flowchart illustrating the operation example of the disconnection determination process illustrated in FIG. 2A.

FIG. 5A is a flowchart illustrating an operation example of voltage measurement illustrated in FIG. 2B.

FIG. 5B is another flowchart illustrating the operation example of the voltage measurement illustrated in FIG. 2B.

FIG. 6 is a waveform chart illustrating an example of voltage measurement in a battery pack in which no disconnection has occurred.

FIG. 7A is an explanatory diagram illustrating an example of measurement results of a cell voltage and a storage battery voltage.

FIG. 7B is another explanatory diagram illustrating the example of the measurement results of the cell voltage and the storage battery voltage.

FIG. 8 is an explanatory diagram illustrating an example of a battery pack in which a disconnection has occurred.

FIG. 9 is a waveform chart illustrating an example of voltage measurement in the battery pack illustrated in FIG. 8.

FIG. 10A is an explanatory diagram illustrating an example of measurement results of the cell voltage and the storage battery voltage in the battery pack illustrated in FIG. 8.

FIG. 10B is another explanatory diagram illustrating the example of the measurement results of the cell voltage and the storage battery voltage in the battery pack illustrated in FIG. 8.

FIG. 11 is a waveform chart illustrating an example of voltage measurement for a second time in the battery pack illustrated in FIG. 8.

FIG. 12A is an explanatory diagram illustrating an example of measurement results of the cell voltage and the storage battery voltage obtained by the voltage measurement for the second time in the battery pack illustrated in FIG. 8.

FIG. 12B is another explanatory diagram illustrating the example of the measurement results of the cell voltage and the storage battery voltage obtained by the voltage measurement for the second time in the battery pack illustrated in FIG. 8.

### DETAILED DESCRIPTION

The present disclosure relates to a battery pack including a storage battery, and to a diagnosis method for the battery pack.

In an apparatus including a storage battery, it is desired to diagnose whether a malfunction has occurred. It is expected also in a battery pack including a storage battery to diagnose whether a malfunction has occurred.

It is desirable to provide a battery pack and a diagnosis method that each make it possible to diagnose whether a malfunction has occurred.

In the following, some example embodiments of the present disclosure are described in detail with reference to the accompanying drawings. Note that the following description is directed to illustrative examples of the present disclosure and not to be construed as limiting to the present disclosure. Factors including, without limitation, numerical values, shapes, materials, components, positions of the components, and how the components are coupled to each other are illustrative only and not to be construed as limiting to the present disclosure. Further, elements in the following example embodiments which are not recited in a most-generic independent claim of the present disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the present disclosure are unillustrated in the drawings.

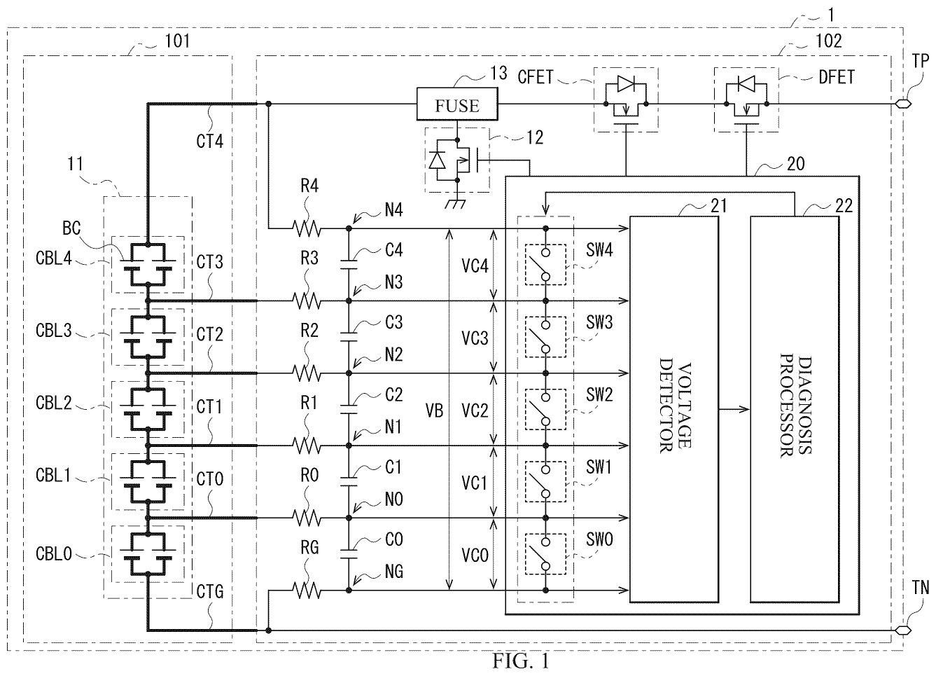

FIG. 1 illustrates a configuration example of a battery pack 1 as a battery pack according to an example embodiment. In this example, the battery pack 1 may be used in equipment that is mainly used outdoors and to which vibration or impact is often applied. Non-limiting examples of such equipment may include outdoor power equipment, such as a mower, and an electrically power-assisted bicycle. The battery pack 1 may include a positive terminal TP, a negative terminal TN, a storage battery 11, transistors DFET and CFET, a transistor 12, a fuse 13, resistors RG and R0 to R4, capacitors C0 to C4, and a microcontroller 20. The storage battery 11 may be provided in a cell holder 101, and the transistors DFET and CFET, the transistor 12, the fuse 13, the resistors RG and R0 to R4, the capacitors C0 to C4, and the microcontroller 20 may be provided on a substrate 102.

The positive terminal TP and the negative terminal TN may be configured to exchange electric power between the battery pack 1 and the equipment on which the battery pack 1 is mounted.

The storage battery 11 may be provided in a path coupling the positive terminal TP and the negative terminal TN to each other, and may be configured to store electric power. The storage battery 11 may include ten battery cells BC in this example. Each of the ten battery cells BC may include a lithium-ion secondary battery in this example. The ten battery cells BC may be separated into five cell blocks CBL (cell blocks CBL0 to CBL4). In one cell block CBL, two battery cells BC may be coupled in parallel. The five cell blocks CBL may be coupled in series. For example, positive electrodes of the two battery cells BC belonging to the cell block CBL0 may be coupled to negative electrodes of the two battery cells BC belonging to the cell block CBL1. Negative electrodes of the two battery cells BC belonging to the cell block CBL0 may be coupled to the negative terminal TN of the battery pack 1. Positive electrodes of the two battery cells BC belonging to the cell block CBL1 may be coupled to negative electrodes of the two battery cells BC belonging to the cell block CBL2. The negative electrodes of the two battery cells BC belonging to the cell block CBL1 may be coupled to the positive electrodes of the two battery cells BC belonging to the cell block CBL0. Positive electrodes of the two battery cells BC belonging to the cell block CBL2 may be coupled to negative electrodes of the two battery cells BC belonging to the cell block CBL3. The negative electrodes of the two battery cells BC belonging to the cell block CBL2 may be coupled to the positive electrodes of the two battery cells BC belonging to the cell block CBL1. Positive electrodes of the two battery cells BC belonging to the cell block CBL3 may be coupled to negative electrodes of the two battery cells BC belonging to the cell block CBL4. The negative electrodes of the two battery cells BC belonging to the cell block CBL3 may be coupled to the positive electrodes of the two battery cells BC belonging to the cell block CBL2. Positive electrodes of the two battery cells BC belonging to the cell block CBL4 may be coupled to the fuse 13. The negative electrodes of the two battery cells BC belonging to the cell block CBL4 may be coupled to the positive electrodes of the two battery cells BC belonging to the cell block CBL3.

The ten battery cells BC in the cell holder 101 may be coupled to wiring of the substrate 102 via six cell tabs CT (cell tabs CTG and CT0 to CT4). In FIG. 1, wiring related to the cell tabs CTG and CT0 to CT4 is indicated by a bold line. Each of the cell tabs CTG and CT0 to CT4 may be a coupling member including a metal material. The negative electrodes of the two battery cells BC belonging to the cell block CBL0 may be coupled to the wiring of the substrate 102 via the cell tab CTG. For example, the cell tab CTG may be coupled to the negative electrodes of the two battery cells BC by welding, and coupled to the wiring of the substrate 102 by welding or soldering. Similarly, the positive electrodes of the two battery cells BC belonging to the cell block CBL0 and the negative electrodes of the two battery cells BC belonging to the cell block CBL1 may be coupled to the wiring of the substrate 102 via the cell tab CT0. The positive electrodes of the two battery cells BC belonging to the cell block CBL1 and the negative electrodes of the two battery cells BC belonging to the cell block CBL2 may be coupled to the wiring of the substrate 102 via the cell tab CT1. The positive electrodes of the two battery cells BC belonging to the cell block CBL2 and the negative electrodes of the two battery cells BC belonging to the cell block CBL3 may be coupled to the wiring of the substrate 102 via the cell tab CT2. The positive electrodes of the two battery cells BC belonging to the cell block CBL3 and the negative electrodes of the two battery cells BC belonging to the cell block CBL4 may be coupled to the wiring of the substrate 102 via the cell tab CT3. The positive electrodes of the two battery cells BC belonging to the cell block CBL4 may be coupled to the wiring of the substrate 102 via the cell tab CT4.

The transistor DFET may be an N-channel field-effect transistor, and may be configured to be turned on and off based on a control signal supplied from the microcontroller 20. The transistor DFET may have a drain coupled to a drain of the transistor CFET, a source coupled to the positive terminal TP of the battery pack 1, and a gate to which the control signal supplied from the microcontroller 20 is applied. As illustrated in FIG. 1, the transistor DFET may include a body diode. The body diode may have an anode coupled to the source of the body of the transistor DFET, and a cathode coupled to the drain of the body of the transistor DFET. The transistor DFET may be put into the off state based on the control signal supplied from the microcontroller 20, for example, when the storage battery 11 is not to be discharged or when an abnormality occurs in the battery pack 1 and the battery pack 1 is to be made permanently unusable thereafter. Thus, the transistor DFET may cut off a discharge current in the battery pack 1.

The transistor CFET may be an N-channel field-effect transistor, and may be configured to be turned on and off based on a control signal supplied from the microcontroller 20. The transistor CFET may have the drain coupled to the drain of the transistor DFET, a source coupled to the fuse 13, and a gate to which the control signal supplied from the microcontroller 20 is applied. As illustrated in FIG. 1, the transistor CFET may include a body diode, as with the transistor DFET. The transistor CFET may be put into the off state based on the control signal supplied from the microcontroller 20, for example, when the storage battery 11 is not to be discharged or when an abnormality occurs in the battery pack 1 and the battery pack 1 is to be made permanently unusable thereafter. Thus, the transistor CFET may cut off a charge current in the battery pack 1.

The transistor 12 may be an N-channel field-effect transistor, and may be configured to pass a current to the fuse 13 by being turned on and off based on a control signal supplied from the microcontroller 20. The transistor 12 may have a drain coupled to a control terminal of the fuse 13, a source grounded, and a gate to which the control signal supplied from the microcontroller 20 is applied.

The fuse 13 may be configured to be blown based on the current supplied from the transistor 12. The fuse 13 may have one end coupled to the source of the transistor CFET, another end coupled to the cell tab CT4, and the control terminal coupled to the drain of the transistor 12. The fuse 13 may be burnt out into the blown state, for example, when an abnormality occurs in the battery pack 1 and the battery pack 1 is to be made permanently unusable thereafter. Thus, the fuse 13 may cut off the charge current and the discharge current in the battery pack 1.

The resistor RG may have one end coupled to the cell tab CTG and coupled to the negative terminal TN of the battery pack 1, and another end coupled to a node NG. The resistor R0 may have one end coupled to the cell tab CT0, and another end coupled to a node N0. The resistor R1 may have one end coupled to the cell tab CT1, and another end coupled to a node N1. The resistor R2 may have one end coupled to the cell tab CT2, and another end coupled to a node N2. The resistor R3 may have one end coupled to the cell tab CT3, and another end coupled to a node N3. The resistor R4 may have one end coupled to the cell tab CT4 and coupled to the fuse 13, and another end coupled to a node N4.

The capacitor C0 may have one end coupled to the node N0, and another end coupled to the node NG. In other words, the capacitor C0 may be provided in a parallel path of the two battery cells BC belonging to the cell block CBL0. Similarly, the capacitor C1 may have one end coupled to the node N1, and another end coupled to the node N0. The capacitor C2 may have one end coupled to the node N2, and another end coupled to the node N1. The capacitor C3 may have one end coupled to the node N3, and another end coupled to the node N2. The capacitor C4 may have one end coupled to the node N4, and another end coupled to the node N3.

The microcontroller 20 may be configured to monitor a state of the battery pack 1 and to control operations of the transistors CFET and DFET and the fuse 13. The microcontroller 20 may include five switches SW (switches SW0 to SW4), a voltage detector 21, and a diagnosis processor 22.

The switch SW0 may have one end coupled to the node N0, and another end coupled to the node NG. In other words, the switch SW0 may be provided in the parallel path of the two battery cells BC belonging to the cell block CBL0. Similarly, the switch SW1 may have one end coupled to the node N1, and another end coupled to the node N0. The switch SW2 may have one end coupled to the node N2, and another end coupled to the node N1. The switch SW3 may have one end coupled to the node N3, and another end coupled to the node N2. The switch SW4 may have one end coupled to the node N4, and another end coupled to the node N3. Each of the switches SW0 to SW4 may be configured to be individually set to the on state or the off state, based on a control signal supplied from the diagnosis processor 22.

The voltage detector 21 may include an AD converter, and may be configured to detect cell voltages VC0 to VC4 and a storage battery voltage VB, based on voltages at the nodes NG and N0 to N4. The cell voltage VC0 may be the voltage of the node N0 with reference to the voltage of the node NG, and may correspond to cell voltages VC of the two battery cells BC belonging to the cell block CBL0. The cell voltage VC1 may be the voltage of the node N1 with reference to the voltage of the node N0, and may correspond to cell voltages VC of the two battery cells BC belonging to the cell block CBL1. The cell voltage VC2 may be the voltage of the node N2 with reference to the voltage of the node N1, and may correspond to cell voltages VC of the two battery cells BC belonging to the cell block CBL2. The cell voltage VC3 may be the voltage of the node N3 with reference to the voltage of the node N2, and may correspond to cell voltages VC of the two battery cells BC belonging to the cell block CBL3. The cell voltage VC4 may be the voltage of the node N4 with reference to the voltage of the node N3, and may correspond to cell voltages VC of the two battery cells BC belonging to the cell block CBL4. The storage battery voltage VB may be the voltage of the node N4 with reference to the voltage of the node NG, and may correspond to a voltage of the whole storage battery 11.

The diagnosis processor 22 may be configured to perform a diagnosis process, based on a detection result of the voltage detector 21.

For example, when the cell voltages VC0 to VC4 are unbalanced, the diagnosis processor 22 may control operations of the switches SW0 to SW4 to make the cell voltages VC0 to VC4 substantially the same voltage as each other. For example, when the cell voltage VC1 is greater than the cell voltages VC0, VC2, VC3, and VC4, the diagnosis processor 22 may put the switch SW1 into the on state. Thus, a current may flow through the resistor R1, the switch SW1, and the resistor R0 in the parallel path of the two battery cells BC belonging to the cell block CBL1, which allows these two battery cells BC to be discharged and lowers the cell voltage VC1. The diagnosis processor 22 may thereby adjust the cell voltage VC1 to substantially the same voltage as the cell voltages VC0, VC2, VC3, and VC4. In this manner, the diagnosis processor 22 may adjust a state of the storage battery 11 to make the cell voltages VC0 to VC4 substantially the same voltage as each other.

In addition, for example, the diagnosis processor 22 may diagnose whether a disconnection has occurred in paths leading from the battery cells BC to the voltage detector 21 via the cell tabs CT0 to CT3. For example, when the battery pack 1 is used in outdoor power equipment such as a mower or an electrically power-assisted bicycle, vibration can cause a disconnection due to damage to the cell tab CT itself, a disconnection due to decoupling between the cell tab CT and the battery cell BC, or a disconnection due to decoupling between the cell tab CT and the wiring of the substrate 102. As will be described later, the diagnosis processor 22 may, for example, put the even-numbered switches and the odd-numbered switches out of the switches SW0 to SW4 into the on state in different periods. Further, the diagnosis processor 22 may detect a disconnection and identify a location where the disconnection is, based on the cell voltages VC0 to VC4 before and after the period of putting the even-numbered switches into the on state and the cell voltages VC0 to VC4 before and after the period of putting the odd-numbered switches into the on state. When there is the disconnection, the diagnosis processor 22 may fix the transistors CFET and DFET in the off state. Without being limited thereto, in some embodiments, the diagnosis processor 22 may, for example, blow the fuse 13 by turning on the transistor 12. Thus, the battery pack 1 may make the battery pack 1 permanently unusable.

The storage battery 11 may correspond to a specific but non-limiting example of a “storage battery” in one embodiment of the present disclosure. The battery cell BC may correspond to a specific but non-limiting example of a “battery cell” in one embodiment of the present disclosure. The switches SW0 to SW4 may correspond to a specific but non-limiting example of “switches” in one embodiment of the present disclosure. The voltage detector 21 may correspond to a specific but non-limiting example of a “voltage detection circuit” in one embodiment of the present disclosure. The cell voltages VC0 to VC4 may correspond to a specific but non-limiting example of “cell voltages” in one embodiment of the present disclosure. The diagnosis processor 22 may correspond to a specific but non-limiting example of a “diagnosis circuit” in one embodiment of the present disclosure. The storage battery voltage VB may correspond to a specific but non-limiting example of a “storage battery voltage” in one embodiment of the present disclosure. The capacitors C0 to C4 may correspond to a specific but non-limiting example of “capacitors” in one embodiment of the present disclosure. The positive terminal TP may correspond to a specific but non-limiting example of a “first terminal” in one embodiment of the present disclosure. The negative terminal TN may correspond to a specific but non-limiting example of a “second terminal” in one embodiment of the present disclosure. The transistors CFET and DFET may each correspond to a specific but non-limiting example of a “cut-off switch” in one embodiment of the present disclosure. The nodes NG and N0 to N4 may each correspond to a specific but non-limiting example of a “coupling node” in one embodiment of the present disclosure.

Next, an operation and workings of the battery pack 1 of the present example embodiment will be described.

First, an outline of an overall operation of the battery pack 1 will be described with reference to FIG. 1. The storage battery 11 may store electric power. The microcontroller 20 may monitor the state of the battery pack 1 and control the operations of the transistors CFET and DFET and the fuse 13. The switches SW0 to SW4 of the microcontroller 20 may be individually set to the on state or the off state, based on the control signal supplied from the diagnosis processor 22. The voltage detector 21 may detect the cell voltages VC0 to VC4 and the storage battery voltage VB, based on the voltages at the nodes NG and N0 to N4. For example, when the cell voltages VC0 to VC4 are unbalanced, the diagnosis processor 22 may control the operations of the switches SW0 to SW4 to make the cell voltages VC0 to VC4 substantially the same voltage as each other. In addition, for example, the diagnosis processor 22 may diagnose a disconnection of the paths leading from the battery cells BC to the voltage detector 21 via the cell tabs CT0 to CT3. The transistors CFET and DFET may be turned on and off based on the control signal supplied from the microcontroller 20. The transistor 12 may pass a current to the fuse 13 based on the control signal supplied from the microcontroller 20, and the fuse 13 may be put into the blown state by this current.

The battery pack 1 may diagnose whether a disconnection has occurred in the paths leading from the battery cells BC to the voltage detector 21 via the cell tabs CT0 to CT3. When a disconnection is detected, the battery pack 1 may fix the transistors CFET and DFET in the off state. Thus, the battery pack 1 may make the battery pack 1 permanently unusable. This operation is described below in detail.

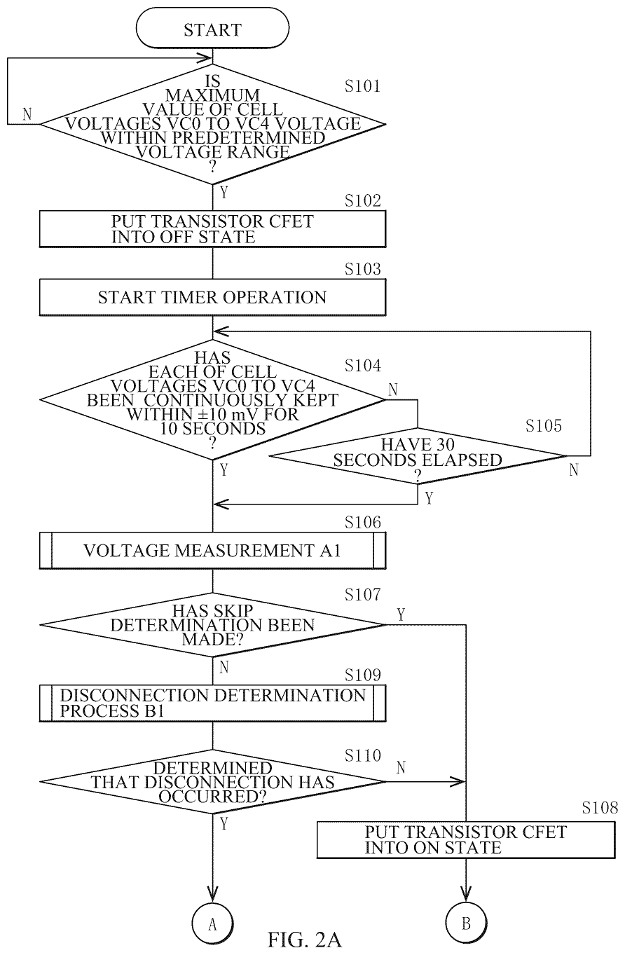

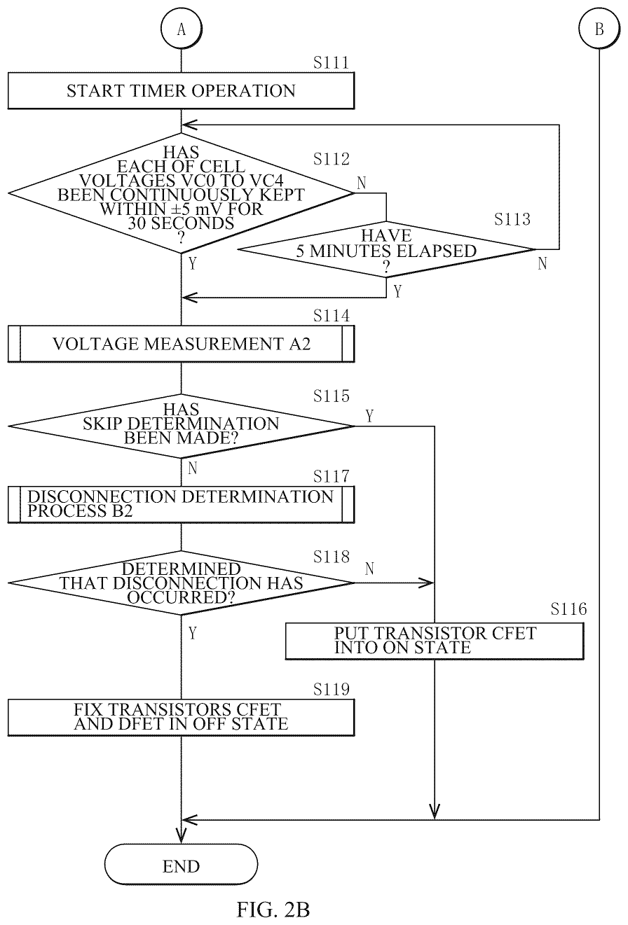

FIGS. 2A and 2B illustrate an example of a disconnection diagnosis process. In this example, the battery pack 1 may perform charging by putting the transistor CFET and the transistor DFET into the on state. Thus, the cell voltages VC0 to VC4 may gradually increase. In a period in which the charging is being performed, the battery pack 1 may temporarily stop the charging and perform a disconnection diagnosis.

First, the diagnosis processor 22 may check whether a maximum value of the cell voltages VC0 to VC4 is a voltage within a predetermined voltage range (step S101). The predetermined voltage range may be greater than or equal to 3900 mV and less than 4050 mV in this example. In the storage battery 11, each of the cell voltages VC0 to VC4 may be larger for a higher charge state. In this example, each of the cell voltages VC0 to VC4 may be about 3900 mV when the charge state is about 70%. When the charge state is low, the cell voltages VC0 to VC4 may vary greatly, which can cause a misdiagnosis to be made in the disconnection diagnosis. Accordingly, the diagnosis processor 22 may perform the disconnection diagnosis when the charge state becomes about 70%. If the maximum value of the cell voltages VC0 to VC4 is not a voltage within the predetermined voltage range (“N” in step S101), the diagnosis processor 22 may repeat step S101 until the maximum value of the cell voltages VC0 to VC4 becomes a voltage within the predetermined voltage range.

If the maximum value of the cell voltages VC0 to VC4 is a voltage within the predetermined voltage range (“Y” in step S101), the diagnosis processor 22 may put the transistor CFET into the off state (step S102). Thus, the battery pack 1 may stop the charging.

When the battery pack 1 has been performing the charging in a state of being coupled to the main body of the equipment, for example, thus stopping the charging may allow the battery pack 1 to supply electric power to the main body of the equipment. In other words, in the battery pack 1, a discharge current may flow in the order of the negative terminal TN, the storage battery 11, the fuse 13, the body diode of the transistor CFET, the transistor DFET, and the positive terminal TP. The battery pack 1 may monitor the discharge current in this disconnection diagnosis process. When the discharge current is greater than or equal to a predetermined current (e.g., 200 mA), the battery pack 1 may stop the disconnection diagnosis process, and put the transistor CFET into the on state to resume the charging. In other words, when the discharge current is thus large, the cell voltage VC is lowered, which lowers a diagnosis accuracy in the disconnection diagnosis process. Accordingly, the battery pack 1 may stop the disconnection diagnosis process and resume the charging when the discharge current is large.

Thereafter, the diagnosis processor 22 may start an operation of a timer (step S103).

Further, the diagnosis processor 22 may check whether each of the cell voltages VC0 to VC4 has been continuously kept within ±10 mV for 10 seconds (step S104). In other words, the diagnosis processor 22 may check whether the cell voltages VC0 to VC4 are stable. If each of the cell voltages VC0 to VC4 has not been continuously kept within ±10 mV for 10 seconds (“N” in step S104), the diagnosis processor 22 may check whether 30 seconds have elapsed from the start of the timer operation in step S103 (step S105). If 30 seconds have not elapsed yet (“N” in step S105), the process may return to step S104.

If each of the cell voltages VC0 to VC4 has been continuously kept within ±10 mV for 10 seconds in step S104, and if 30 seconds have elapsed from the start of the timer operation in step S105, the microcontroller 20 may perform voltage measurement A1 (step S106).

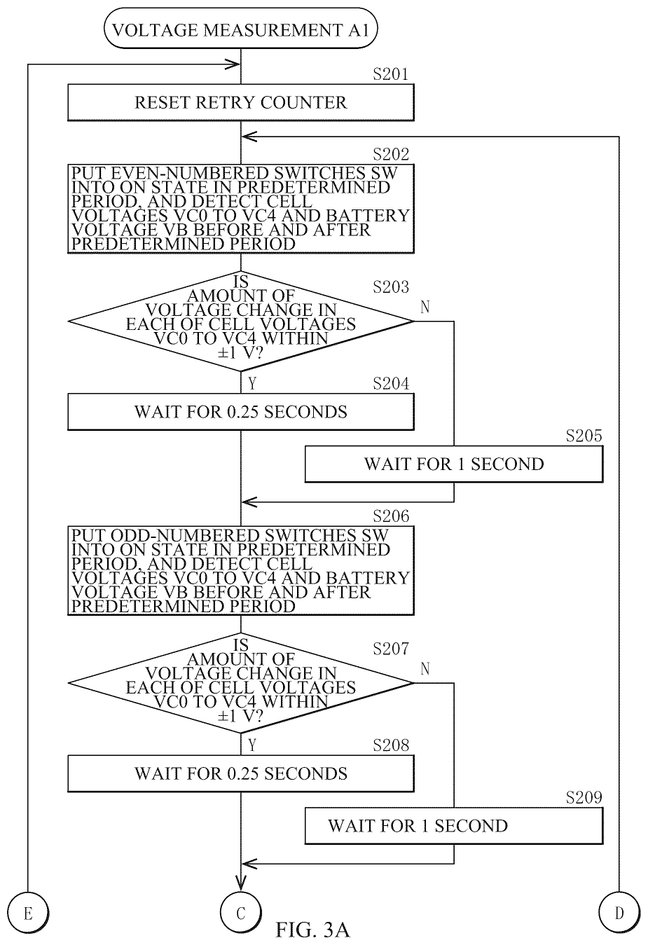

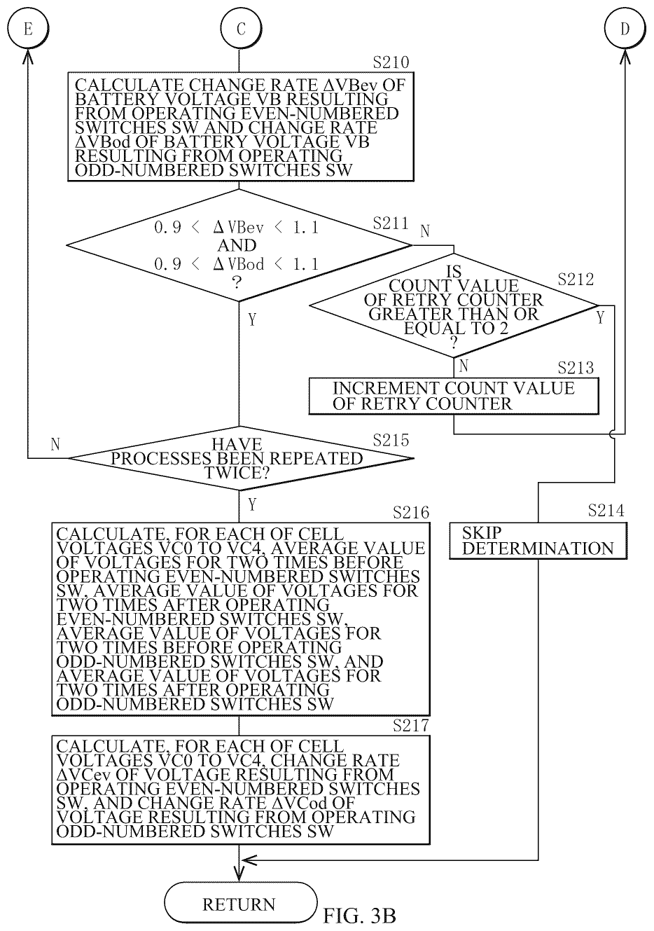

FIGS. 3A and 3B illustrate an example of a subroutine of the voltage measurement A1.

First, the microcontroller 20 may reset a retry counter (step S201). For example, the microcontroller 20 may set a count value of the retry counter to 0.

Thereafter, the microcontroller 20 may put the even-numbered switches SW (the switches SW0, SW2, and SW4) out of the switches SW0 to SW4 into the on state in a predetermined period, and detect the cell voltages VC0 to VC4 and the storage battery voltage VB before and after the predetermined period (step S202). For example, first, the voltage detector 21 may detect the cell voltages VC0 to VC4 and the storage battery voltage VB in a period in which the switches SW0 to SW4 are in the off state. Thereafter, the diagnosis processor 22 may put the even-numbered switches SW (the switches SW0, SW2, and SW4) into the on state in the predetermined period. The switches SW1 and SW3 may be kept in the off state. The predetermined period may have a time length of, for example, 5 milliseconds. Further, the voltage detector 21 may detect the cell voltages VC0 to VC4 and the storage battery voltage VB, for example, 30 milliseconds after the predetermined period ends and the even-numbered switches SW (the switches SW0, SW2, and SW4) return to the off state.

Thereafter, the diagnosis processor 22 may check whether an amount of voltage change in each of the cell voltages VC0 to VC4, between before and after the predetermined period, is within ±1 V (step S203). If the amount of voltage change in each of the cell voltages VC0 to VC4 is within ±1 V (“Y” in step S203), the microcontroller 20 may wait for 0.25 seconds (step S204). If the amount of voltage change in one or more of the cell voltages VC0 to VC4 exceeds ±1 V (“N” in step S203), the microcontroller 20 may wait for 1 second (step S205).

In other words, as will be described later, there is a possibility that a disconnection has occurred when the amount of voltage change in one or more of the cell voltages VC0 to VC4 exceeds ±1 V. Accordingly, in this case, the microcontroller 20 may wait for 1 second in order to provide time until the voltage returns to the original voltage to some extent. In contrast, it is unlikely that a disconnection has occurred when the amount of voltage change in each of the cell voltages VC0 to VC4 is within ±1 V. Accordingly, in this case, the microcontroller 20 may wait for 0.25 seconds in order to shorten time taken for the disconnection diagnosis process.

Thereafter, the microcontroller 20 may put the odd-numbered switches SW (the switches SW1 and SW3) out of the switches SW0 to SW4 into the on state in a predetermined period, and detect the cell voltages VC0 to VC4 and the storage battery voltage VB before and after the predetermined period (step S206). For example, first, the voltage detector 21 may detect the cell voltages VC0 to VC4 and the storage battery voltage VB in a period in which the switches SW0 to SW4 are in the off state. Thereafter, the diagnosis processor 22 may put the odd-numbered switches SW (the switches SW1 and SW3) into the on state in the predetermined period. The switches SW0, SW2, and SW4 may be kept in the off state. The predetermined period may have a time length of, for example, 5 milliseconds. Further, the voltage detector 21 may detect the cell voltages VC0 to VC4 and the storage battery voltage VB, for example, 30 milliseconds after the predetermined period ends and the odd-numbered switches SW (the switches SW1 and SW3) return to the off state.

Thereafter, the diagnosis processor 22 may check whether an amount of voltage change in each of the cell voltages VC0 to VC4, between before and after the predetermined period, is within ±1 V (step S207). If the amount of voltage change in each of the cell voltages VC0 to VC4 is within ±1 V (“Y” in step S207), the microcontroller 20 may wait for 0.25 seconds (step S208). If the amount of voltage change in one or more of the cell voltages VC0 to VC4 exceeds ±1 V (“N” in step S207), the microcontroller 20 may wait for 1 second (step S209).

Thereafter, the diagnosis processor 22 may calculate a change rate ΔVBev of the storage battery voltage VB resulting from operating the even-numbered switches SW in step S202 and a change rate ΔVBod of the storage battery voltage VB resulting from operating the odd-numbered switches SW in step S206 (step S210). For example, the diagnosis processor 22 may calculate the change rate ΔVBev by dividing the storage battery voltage VB after operating the even-numbered switches SW by the storage battery voltage VB before operating the even-numbered switches SW in step S202. In addition, the diagnosis processor 22 may calculate the change rate ΔVBod by dividing the storage battery voltage VB after operating the odd-numbered switches SW by the storage battery voltage VB before operating the odd-numbered switches SW in step S206.

Thereafter, the diagnosis processor 22 may check whether the change rate ΔVBev of the storage battery voltage VB is greater than 0.9 and less than 1.1 and the change rate ΔVBod of the storage battery voltage VB is greater than 0.9 and less than 1.1 (step S211). In other words, the storage battery voltage VB is expected not to change greatly in steps S202 and S206. However, the storage battery voltage VB can change greatly by, for example, being influenced by noise from the outside of the battery pack 1. In this case, it is presumed that the detection results of the cell voltages VC0 to VC4 in steps S202 and S206 are also influenced by the noise, and the disconnection diagnosis is thus not to be performed based on these detection results. Accordingly, the diagnosis processor 22 may confirm that the storage battery voltage VB has not changed greatly in step S211.

If the change rate ΔVBev, the change rate ΔVBod, or both of the storage battery voltage VB do not satisfy the condition in step S211 (“N” in step S211), the diagnosis processor 22 may check whether the count value of the retry counter is greater than or equal to 2 (step S212). If the count value of the retry counter is less than 2 (“N” in step S212), the diagnosis processor 22 may increment the count value of the retry counter (step S213), and the process may return to step S202. Thus, the microcontroller 20 may perform re-measurement. If the count value of the retry counter is greater than or equal to 2 (“Y” in step S212), the microcontroller 20 may make a skip determination that the disconnection diagnosis process is to be skipped (step S214). Thus, the subroutine of the voltage measurement A1 may end.

If the change rate ΔVBev and the change rate ΔVBod of the storage battery voltage VB each satisfy the condition in step S211 (“Y” in step S211), the diagnosis processor 22 may check whether the processes of steps S201 to S211 have been repeated twice (step S215). If these processes have not yet been repeated twice (“N”in step S215), the process may return to step S201.

If the processes of steps S201 to S211 have been repeated twice in step S215 (“Y” in step S215), the diagnosis processor 22 may calculate, for each of the cell voltages VC0 to VC4, an average value of the voltages for the two times before operating the even-numbered switches SW (the switches SW0, SW2, and SW4), an average value of the voltages for the two times after operating the even-numbered switches SW, an average value of the voltages for the two times before operating the odd-numbered switches SW (the switches SW1 and SW3), and an average value of the voltages for the two times after operating the odd-numbered switches SW (step S216). For example, the diagnosis processor 22 may calculate each of the average value of the cell voltages VC0, the average value of the cell voltages VC1, the average value of the cell voltages VC2, the average value of the cell voltages VC3, and the average value of the cell voltages VC4, before putting the even-numbered switches SW into the on state, detected in the first step S202 and the second step S202. The diagnosis processor 22 may also calculate each of the average value of the cell voltages VC0, the average value of the cell voltages VC1, the average value of the cell voltages VC2, the average value of the cell voltages VC3, and the average value of the cell voltages VC4, after putting the even-numbered switches SW into the on state, detected in the first step S202 and the second step S202. The diagnosis processor 22 may also calculate each of the average value of the cell voltages VC0, the average value of the cell voltages VC1, the average value of the cell voltages VC2, the average value of the cell voltages VC3, and the average value of the cell voltages VC4, before putting the odd-numbered switches SW into the on state, detected in the first step S206 and the second step S206. The diagnosis processor 22 may also calculate each of the average value of the cell voltages VC0, the average value of the cell voltages VC1, the average value of the cell voltages VC2, the average value of the cell voltages VC3, and the average value of the cell voltages VC4, after putting the odd-numbered switches SW into the on state, detected in the first step S206 and the second step S206.

Thereafter, the diagnosis processor 22 may calculate, for each of the cell voltages VC0 to VC4, a change rate ΔVCev of the voltage resulting from operating the even-numbered switches SW, and a change rate ΔVCod of the voltage resulting from operating the odd-numbered switches SW, based on a calculation result in step S216 (step S217). The diagnosis processor 22 may thus calculate change rates ΔVC0ev, ΔVC1ev, ΔVC2ev, ΔVC3ev, and ΔVC4ev and change rates ΔVC0od, ΔVC1od, ΔVC2od, ΔVC3od, and ΔVC4od. For example, the diagnosis processor 22 may calculate the change rate ΔVC0ev of the cell voltage VC0 by dividing the average value of the cell voltages VC0 for the two times after operating the even-numbered switches SW by the average value of the cell voltages VC0 for the two times before operating the even-numbered switches SW. Similarly, the diagnosis processor 22 may calculate the change rate ΔVC1ev of the cell voltage VC1, the change rate ΔVC2ev of the cell voltage VC2, the change rate ΔVC3ev of the cell voltage VC3, and the change rate ΔVC4ev of the cell voltage VC4 resulting from operating the even-numbered switches SW. The diagnosis processor 22 may also calculate the change rate ΔVC0od of the cell voltage VC0 by dividing the average value of the cell voltages VC0 for the two times after operating the odd-numbered switches SW by the average value of the cell voltages VC0 for the two times before operating the odd-numbered switches SW. Similarly, the diagnosis processor 22 may calculate the change rate ΔVC1od of the cell voltage VC1, the change rate ΔVC2od of the cell voltage VC2, the change rate ΔVC3od of the cell voltage VC3, and the change rate ΔVC4od of the cell voltage VC4 resulting from operating the odd-numbered switches SW.

This may be the end of the subroutine of the voltage measurement A1.

Thereafter, as illustrated in FIG. 2A, the diagnosis processor 22 may check whether the skip determination has been made in step S214 of the voltage measurement A1 illustrated in FIGS. 3A and 3B (step S107). If the skip determination has been made (“Y” in step S107), the diagnosis processor 22 may put the transistor CFET into the on state (step S108). Thus, the battery pack 1 may interrupt the disconnection diagnosis process and resume the charging. This may be the end of this flow.

If the skip determination has not been made (“N” in step S107), the microcontroller 20 may perform a disconnection determination process B1 (step S109).

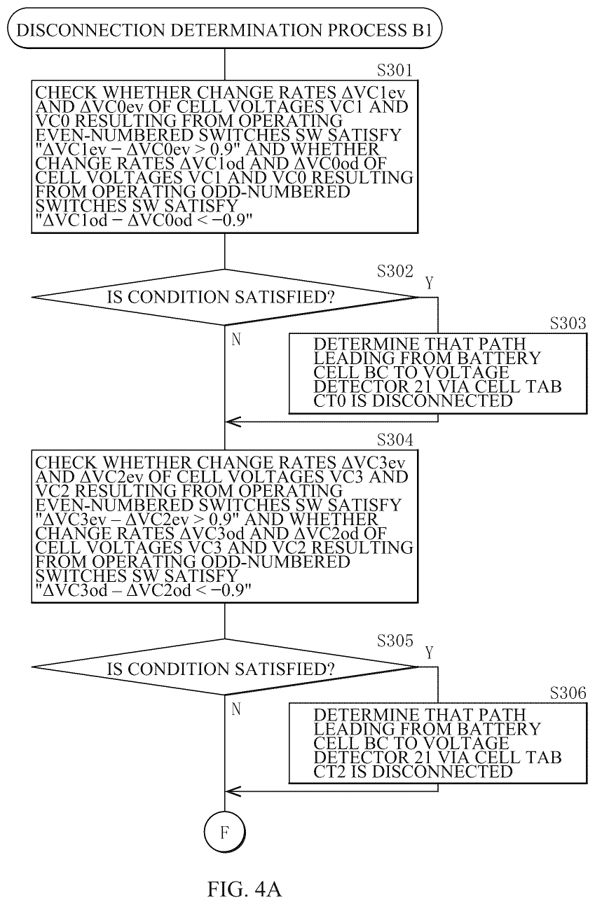

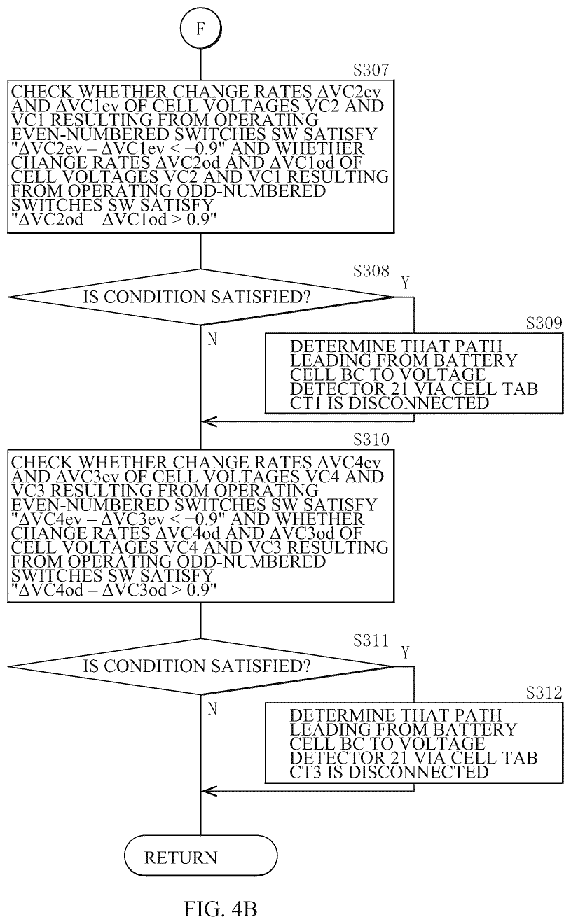

FIGS. 4A and 4B illustrate an example of a subroutine of the disconnection determination process B1.

First, the diagnosis processor 22 may check whether the change rates ΔVC1ev and ΔVC0ev of the cell voltages VC1 and VC0 resulting from operating the even-numbered switches SW (the switches SW0, SW2, and SW4) satisfy “ΔVC1ev−ΔVC0ev>0.9”, and the change rates ΔVC1od and ΔVC0od of the cell voltages VC1 and VC0 resulting from operating the odd-numbered switches SW (the switches SW1 and SW3) satisfy “ΔVC1od−ΔVC0od<−0.9” (step S301). Note that these values “0.9” and “−0.9” are examples, and may be changed as appropriate depending on, for example, a circuit configuration.

If the condition in step S301 is satisfied (“Y” in step S302), the diagnosis processor 22 may determine that the path leading from the battery cell BC to the voltage detector 21 via the cell tab CT0 is disconnected (step S303). Further, the process may proceed to step S304. If the condition in step S301 is not satisfied (“N”in step S302), the process may proceed to step S304.

Thereafter, the diagnosis processor 22 may check whether the change rates ΔVC3ev and ΔVC2ev of the cell voltages VC3 and VC2 resulting from operating the even-numbered switches SW (the switches SW0, SW2, and SW4) satisfy “ΔVC3ev−ΔVC2ev>0.9”, and the change rates ΔVC3od and ΔVC2od of the cell voltages VC3 and VC2 resulting from operating the odd-numbered switches SW (the switches SW1 and SW3) satisfy “ΔVC3od−ΔVC2od<−0.9” (step S304).

If the condition in step S304 is satisfied (“Y” in step S305), the diagnosis processor 22 may determine that the path leading from the battery cell BC to the voltage detector 21 via the cell tab CT2 is disconnected (step S306). Further, the process may proceed to step S307. If the condition in step S304 is not satisfied (“N” in step S305), the process may proceed to step S307.

Thereafter, the diagnosis processor 22 may check whether the change rates ΔVC2ev and ΔVC1ev of the cell voltages VC2 and VC1 resulting from operating the even-numbered switches SW (the switches SW0, SW2, and SW4) satisfy “ΔVC2ev−ΔVC1ev<−0.9”, and the change rates ΔVC2od and ΔVC1od of the cell voltages VC2 and VC1 resulting from operating the odd-numbered switches SW (the switches SW1 and SW3) satisfy “ΔVC2od−ΔVC1od>0.9” (step S307).

If the condition in step S307 is satisfied (“Y” in step S308), the diagnosis processor 22 may determine that the path leading from the battery cell BC to the voltage detector 21 via the cell tab CT1 is disconnected (step S309). Further, the process may proceed to step S310. If the condition in step S307 is not satisfied (“N”in step S308), the process may proceed to step S310.

Thereafter, the diagnosis processor 22 may check whether the change rates ΔVC4ev and ΔVC3ev of the cell voltages VC4 and VC3 resulting from operating the even-numbered switches SW (the switches SW0, SW2, and SW4) satisfy “ΔVC4ev−ΔVC3ev<−0.9”, and the change rates ΔVC4od and ΔVC3od of the cell voltages VC4 and VC3 resulting from operating the odd-numbered switches SW (the switches SW1 and SW3) satisfy “ΔVC4od−ΔVC3od>0.9” (step S310).

If the condition in step S310 is satisfied (“Y” in step S311), the diagnosis processor 22 may determine that the path leading from the battery cell BC to the voltage detector 21 via the cell tab CT3 is disconnected (step S312). Further, the subroutine of the disconnection determination process B1 may end. If the condition in step S310 is not satisfied (“N” in step S311), the subroutine of the disconnection determination process B1 may end.

Thereafter, as illustrated in FIG. 2A, the diagnosis processor 22 may check whether it is determined that a disconnection has occurred in the disconnection determination process B1 illustrated in FIGS. 4A and 4B (step S110). If no disconnection has occurred (“N” in step S110), the diagnosis processor 22 may put the transistor CFET into the on state (step S108). Thus, the battery pack 1 may resume the charging. This may be the end of this flow. In other words, having confirmed that no disconnection has occurred in the disconnection diagnosis process, the diagnosis processor 22 may end the disconnection diagnosis process.

If a disconnection has occurred in step S110 (“Y” in step S110), the microcontroller 20 may perform processes similar to the processes of steps S103 to S110 with higher accuracy, and re-confirm that the disconnection has occurred.

First, the diagnosis processor 22 may start the operation of the timer (step S111).

Further, the diagnosis processor 22 may check whether each of the cell voltages VC0 to VC4 has been continuously kept within ±5 mV for 30 seconds (step S112). The conditions in steps S112 and S113 may be set to conditions stricter than the conditions in steps S104 and S105. Thus, the diagnosis processor 22 may check whether the cell voltages VC0 to VC4 are stable. If each of the cell voltages VC0 to VC4 has not been continuously kept within ±5 mV for 30 seconds (“N” in step S112), the diagnosis processor 22 may check whether 5 minutes have elapsed from the start of the timer operation in step S111 (step S113). If 5 minutes have not elapsed yet (“N” in step S113), the process may return to step S112.

If each of the cell voltages VC0 to VC4 has been continuously kept within ±5 mV for 30 seconds in step S112, and if 5 minutes have elapsed from the start of the timer operation in step S113, the microcontroller 20 may perform voltage measurement A2 (step S114).

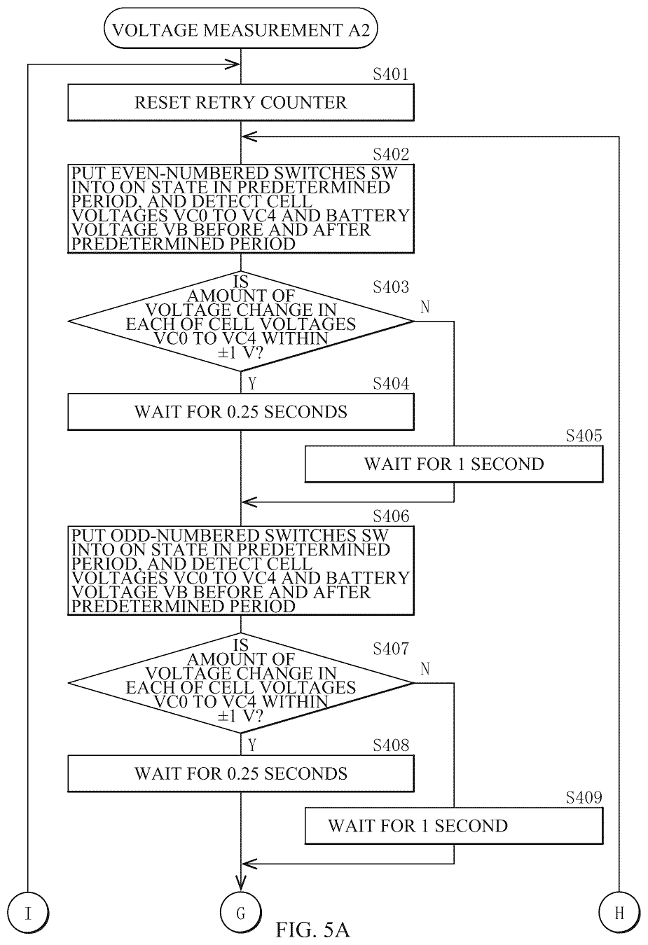

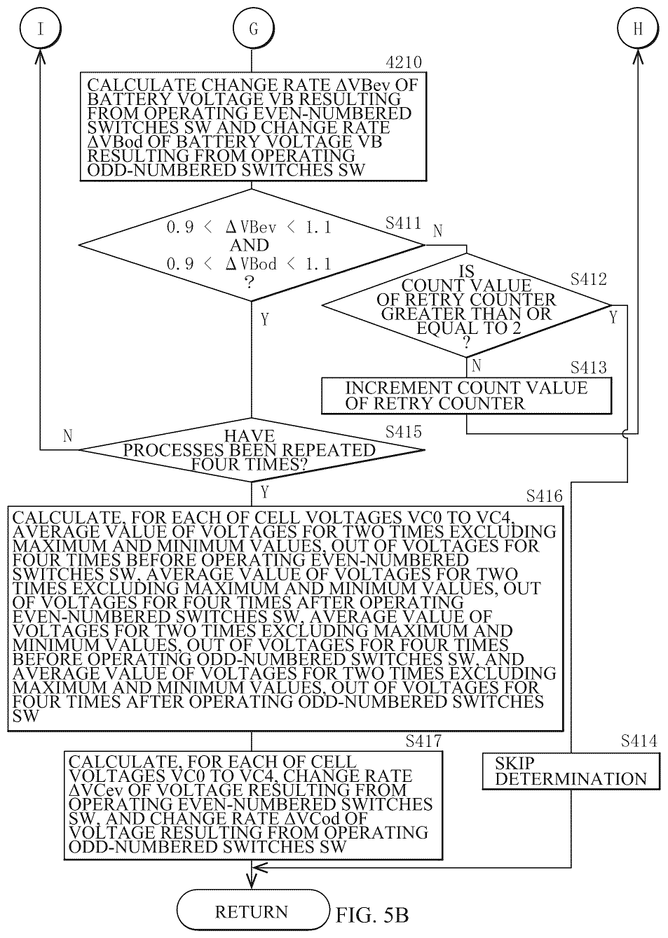

FIGS. 5A and 5B illustrate an example of a subroutine of the voltage measurement A2. Steps S401 to S414 in the voltage measurement A2 may be similar to steps S201 to S214 in the voltage measurement A1 illustrated in FIGS. 3A and 3B.

In the voltage measurement A2, the processes of steps S401 to S411 may be repeated four times. In other words, although the diagnosis processor 22 may check whether the processes of steps S201 to S211 have been repeated twice in step S215 in the voltage measurement A1 (FIGS. 3A and 3B), in the voltage measurement A2, the diagnosis processor 22 may check whether the processes of steps S401 to S411 have been repeated four times in step S415.

If the processes of step S401 to S411 have been repeated four times in step S415 (“Y” in step S415), the diagnosis processor 22 may calculate, for each of the cell voltages VC0 to VC4, an average value of voltages for two times excluding a maximum value and a minimum value, out of the voltages for the four times before operating the even-numbered switches SW (the switches SW0, SW2, and SW4), an average value of voltages for two times excluding a maximum value and a minimum value, out of the voltages for the four times after operating the even-numbered switches SW, an average value of voltages for two times excluding a maximum value and a minimum value, out of the voltages for the four times before operating the odd-numbered switches SW (the switches SW1 and SW3), and an average value of voltages for two times excluding a maximum value and a minimum value, out of the voltages for the four times after operating the odd-numbered switches SW (step S416). Thus, the diagnosis processor 22 may calculate the average value of the remaining two voltages, excluding the maximum value and the minimum value, out of the voltages for the four times, which makes it possible to increase the accuracy of the disconnection diagnosis.

Thereafter, the diagnosis processor 22 may calculate, for each of the cell voltages VC0 to VC4, a change rate ΔVCev of the voltage resulting from operating the even-numbered switches SW, and a change rate ΔVCod of the voltage resulting from operating the odd-numbered switches SW, based on a calculation result in step S416 (step S417). For example, the diagnosis processor 22 may calculate the change rate ΔVCev (the change rate ΔVC0ev) of the cell voltage VC0 by dividing the average value of the cell voltages VC0 for the two times after operating the even-numbered switches SW by the average value of the cell voltages VC0 for the two times before operating the even-numbered switches SW. Similarly, the diagnosis processor 22 may calculate the change rate ΔVCev (the change rate ΔVC1ev) of the cell voltage VC1, the change rate ΔVCev (the change rate ΔVC2ev) of the cell voltage VC2, the change rate ΔVCev (the change rate ΔVC3ev) of the cell voltage VC3, and the change rate ΔVCev (the change rate ΔVC4ev) of the cell voltage VC4 resulting from operating the even-numbered switches SW. The diagnosis processor 22 may also calculate the change rate ΔVCod (the change rate ΔVC0od) of the cell voltage VC0 by dividing the average value of the cell voltages VC0 for the two times after operating the odd-numbered switches SW by the average value of the cell voltages VC0 for the two times before operating the odd-numbered switches SW. Similarly, the diagnosis processor 22 may calculate the change rate ΔVCod (the change rate ΔVC1od) of the cell voltage VC1, the change rate ΔVCod (the change rate ΔVC2od) of the cell voltage VC2, the change rate ΔVCod (the change rate ΔVC3od) of the cell voltage VC3, and the change rate ΔVCod (the change rate ΔVC4od) of the cell voltage VC4 resulting from operating the odd-numbered switches SW.

This may be the end of the subroutine of the voltage measurement A2.

Thereafter, as illustrated in FIG. 2B, the diagnosis processor 22 may check whether the skip determination has been made in step S414 of the voltage measurement A2 illustrated in FIGS. 5A and 5B (step S115). If the skip determination has been made (“Y” in step S115), the diagnosis processor 22 may put the transistor CFET into the on state (step S116). Thus, the battery pack 1 may interrupt the disconnection diagnosis process and resume the charging. This may be the end of this flow.

If the skip determination has not been made in the voltage measurement A2 (“N” in step S115), the microcontroller 20 may perform a disconnection determination process B2 (step S117). The disconnection determination process B2 may be similar to the disconnection determination process B1 illustrated in FIGS. 4A and 4B.

Thereafter, the diagnosis processor 22 may check whether it is determined that a disconnection has occurred in the disconnection determination process B2 (step S118). If no disconnection has occurred (“N” in step S118), the diagnosis processor 22 may put the transistor CFET into the on state (step S116). Thus, the battery pack 1 may resume the charging. This may be the end of this flow. In other words, having confirmed that no disconnection has occurred in the diagnosis for the second time performed with higher accuracy than the diagnosis for the first time, the diagnosis processor 22 may end the disconnection diagnosis process.

If a disconnection has occurred in step S118 (“Y” in step S118), the diagnosis processor 22 may fix the transistors CFET and DFET in the off state (step S119). Thus, the battery pack 1 may make the battery pack 1 permanently unusable.

This may be the end of this process.

The predetermined period in step S202, for example, may correspond to a specific but non-limiting example of a “first predetermined period” in one embodiment of the present disclosure. The predetermined period in step S206, for example, may correspond to a specific but non-limiting example of a “second predetermined period” in one embodiment of the present disclosure. The change rate ΔVCev may correspond to a specific but non-limiting example of a “first change rate” in one embodiment of the present disclosure. The change rate ΔVCod may correspond to a specific but non-limiting example of a “second change rate” in one embodiment of the present disclosure.

Next, the disconnection diagnosis process of the battery pack 1 will be described with reference to specific but non-limiting examples. First, a description is given of the disconnection diagnosis process of the battery pack 1 in which no disconnection has occurred, followed by a description of the disconnection diagnosis process of the battery pack 1 in which a disconnection has occurred.

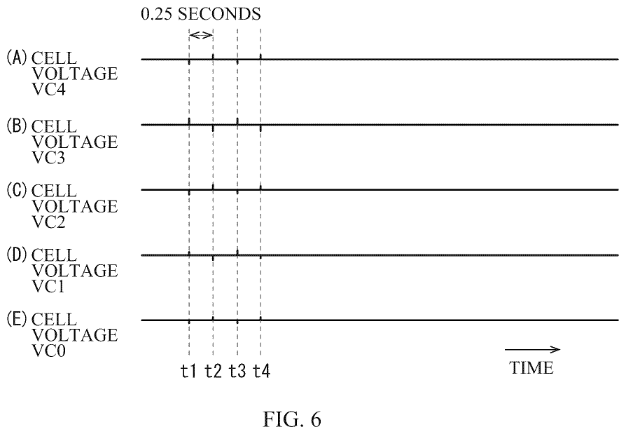

FIG. 6 illustrates an example of the voltage measurement A1 in the battery pack 1 in which no disconnection has occurred. In FIG. 6, part (A) illustrates a waveform of the cell voltage VC4, part (B) illustrates a waveform of the cell voltage VC3, part (C) illustrates a waveform of the cell voltage VC2, part (D) illustrates a waveform of the cell voltage VC1, and part (E) illustrates a waveform of the cell voltage VC0. The horizontal axis in FIG. 6 represents time.

In the first step S202 (FIG. 3A), the diagnosis processor 22 may put the even-numbered switches SW (the switches SW0, SW2, and SW4) into the on state in a short period starting from a timing t1. Note that, because the length of the period of putting the switches SW into the on state is, for example, 5 milliseconds, this period may be very short in a timescale of FIG. 6. For example, when the switch SW0 is put into the on state, the node N1 and the node N0 may be coupled to each other via the switch SW0; thus, the cell voltage VC0 may become smaller (part (E) of FIG. 6). In this manner, at the timing t1 when the switches SW0, SW2, and SW4 are put into the on state, the cell voltages VC0, VC2, and VC4 may become slightly smaller transiently, and thereafter return to the original voltages (parts (A), (C), and (E) of FIG. 6). In contrast, the cell voltages VC1 and VC3 may become slightly larger transiently at the timing t1, and thereafter return to the original voltages (parts (B) and (D) of FIG. 6).

In this example, the cell voltages VC0 to VC4 may hardly change and the amount of voltage change in each of the cell voltages VC0 to VC4 may thus be within ±1 V, between before and after the period of putting the even-numbered switches SW into the on state. Accordingly, the microcontroller 20 may wait for 0.25 seconds (step S204).

Thereafter, in the first step S206 (FIG. 3A), the diagnosis processor 22 may put the odd-numbered switches SW (the switches SW1 and SW3) into the on state in a short period starting from a timing t2. The cell voltages VC1 and VC3 may become slightly smaller transiently at the timing t2, and thereafter return to the original voltages (parts (B) and (D) of FIG. 6). In contrast, the cell voltages VC0, VC2, and VC4 may become slightly larger transiently at the timing t2, and thereafter return to the original voltages (parts (A), (C), and (E) of FIG. 6). In this example, the amount of voltage change in each of the cell voltages VC0 to VC4 may be within ±1 V between before and after the period of putting the odd-numbered switches SW into the on state. Accordingly, the microcontroller 20 may wait for 0.25 seconds (step S208).

Thereafter, in the second step S202, the diagnosis processor 22 may put the even-numbered switches SW (the switches SW0, SW2, and SW4) into the on state in a short period starting from a timing t3. This operation may be substantially similar to the operation at the timing t1. Further, the microcontroller 20 may wait for 0.25 seconds (step S204).

Thereafter, in the second step S206, the diagnosis processor 22 may put the odd-numbered switches SW (the switches SW1 and SW3) into the on state in a short period starting from a timing t4. This operation may be substantially similar to the operation at the timing t2. Further, the microcontroller 20 may wait for 0.25 seconds (step S208).

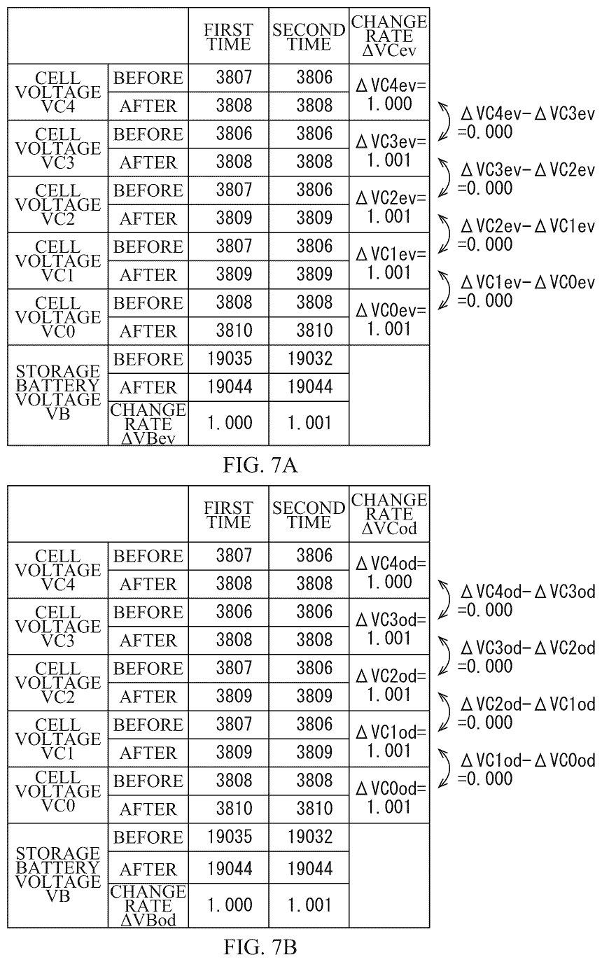

FIG. 7A illustrates an example of the cell voltages VC0 to VC4 and the storage battery voltage VB when the even-numbered switches SW are put into the on state. FIG. 7B illustrates an example of the cell voltages VC0 to VC4 and the storage battery voltage VB when the odd-numbered switches SW are put into the on state. In FIGS. 7A and 7B, the voltages are in mV units.

FIG. 7A illustrates data in the first step S202 and data in the second step S202. In FIG. 7A, “before” indicates before putting the even-numbered switches SW into the on state, and “after” indicates after putting the even-numbered switches SW into the on state. Similarly, FIG. 7B illustrates data in the first step S206 and data in the second step S206. In FIG. 7B, “before” indicates before putting the odd-numbered switches SW into the on state, and “after” indicates after putting the odd-numbered switches SW into the on state.

In step S210 (FIG. 3B), the diagnosis processor 22 may calculate the change rate ΔVBev of the storage battery voltage VB resulting from operating the even-numbered switches SW and the change rate ΔVBod of the storage battery voltage VB resulting from operating the odd-numbered switches SW. Further, in step S211, the diagnosis processor 22 may check whether the change rate ΔVBev of the storage battery voltage VB is greater than 0.9 and less than 1.1 and the change rate ΔVBod of the storage battery voltage VB is greater than 0.9 and less than 1.1.

In this example, as illustrated in FIG. 7A, the change rate ΔVBev of the storage battery voltage VB for the first time and the change rate ΔVBev of the storage battery voltage VB for the second time, resulting from operating the even-numbered switches SW, may be greater than 0.9 and less than 1.1. In addition, as illustrated in FIG. 7B, the change rate ΔVBod of the storage battery voltage VB for the first time and the change rate ΔVBod of the storage battery voltage VB for the second time, resulting from operating the odd-numbered switches SW, may be greater than 0.9 and less than 1.1. Accordingly, the diagnosis processor 22 may determine that there is no influence of noise from the outside of the battery pack 1 and it is possible to perform the disconnection diagnosis based on the detection result of the cell voltages VC0 to VC4.

Further, in steps S216 and S217 (FIG. 3B), the diagnosis processor 22 may calculate the change rates ΔVC0ev, ΔVC1ev, ΔVC2ev, ΔVC3ev, and ΔVC4ev of the cell voltages VC0 to VC4 resulting from operating the even-numbered switches SW, and the change rates ΔVC0od, ΔVC1od, ΔVC2od, ΔVC3od, and ΔVC4od of the cell voltages VC0 to VC4 resulting from operating the odd-numbered switches SW.

Further, in the disconnection determination process B1 (FIGS. 4A and 4B), the diagnosis processor 22 may check whether the change rates ΔVC0ev, ΔVC1ev, ΔVC2ev, ΔVC3ev, and ΔVC4ev of the cell voltages VC0 to VC4 resulting from operating the even-numbered switches SW, and the change rates ΔVC0od, ΔVC1od, ΔVC2od, ΔVC3od, and ΔVC4od of the cell voltages VC0 to VC4 resulting from operating the odd-numbered switches SW satisfy the conditions in steps S301, S304, S307, and S310.

In this example, none of the conditions in steps S301, S304, S307, and S310 may be satisfied, as illustrated in FIGS. 7A and 7B. Accordingly, the diagnosis processor 22 may determine that no disconnection has occurred.

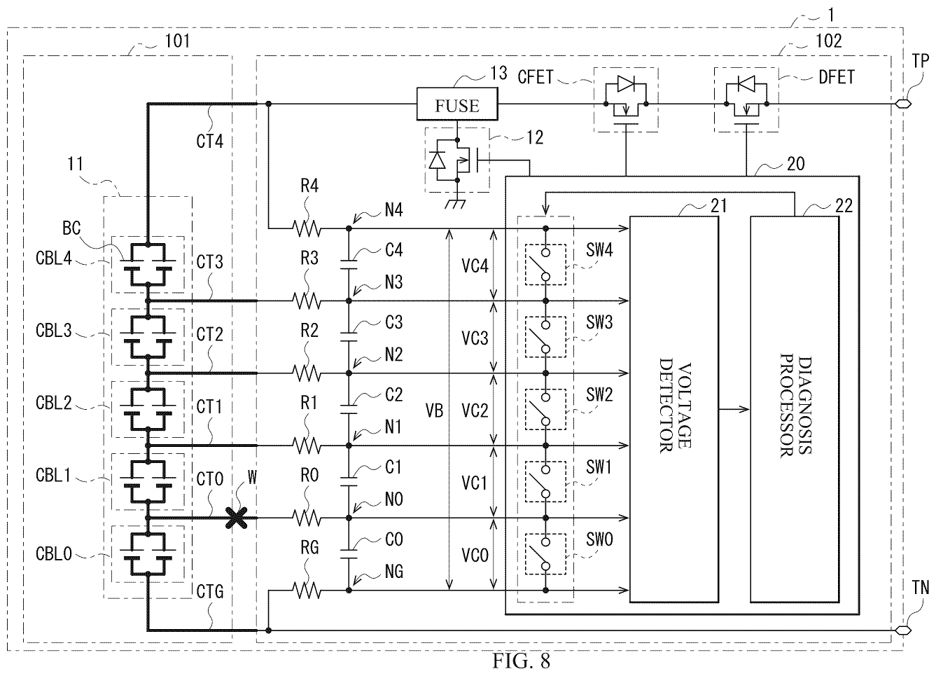

FIG. 8 illustrates an example of the battery pack 1 in which a disconnection has occurred. In this example, as illustrated in FIG. 8, a disconnection may have occurred at a disconnection location W of the cell tab CT0.

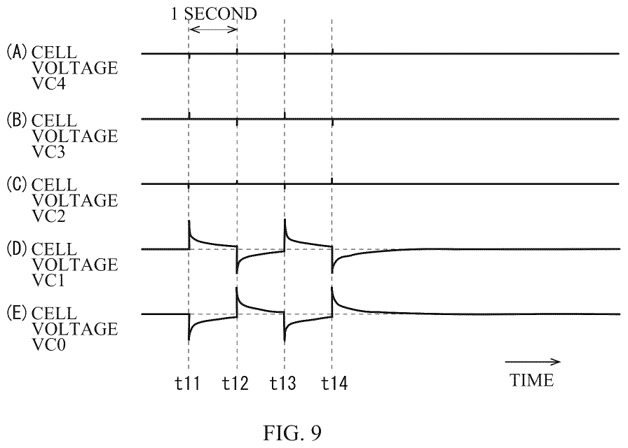

FIG. 9 illustrates an example of the voltage measurement A1 in the battery pack 1 illustrated in FIG. 8. In FIG. 9, part (A) illustrates the waveform of the cell voltage VC4, part (B) illustrates the waveform of the cell voltage VC3, part (C) illustrates the waveform of the cell voltage VC2, part (D) illustrates the waveform of the cell voltage VC1, and part (E) illustrates the waveform of the cell voltage VC0. The horizontal axis in FIG. 9 represents time.

In the first step S202 (FIG. 3A), the diagnosis processor 22 may put the even-numbered switches SW (the switches SW0, SW2, and SW4) into the on state in a short period starting from a timing t11. In this example, because the disconnection has occurred in the cell tab CT0, when the switch SW0 is put into the on state, for example, the voltage of the node N0 may change toward the voltage of the node NG; thus, the cell voltage VC0 may become smaller (part (E) of FIG. 9) and the cell voltage VC1 may become larger (part (D) of FIG. 9). Further, when the switch SW0 is put into the off state, the voltage of the node N0 may slowly change toward the original voltage. This may cause the cell voltages VC0 and VC1 to slowly change toward the original voltages. The cell voltages VC2 to VC4 may be similar to those in FIG. 6 illustrating the case where no disconnection has occurred (parts (A) to (C) of FIG. 9).

In this example, the amount of voltage change in each of the cell voltages VC0 to VC4 may exceed ±1 V, between before and after the period of putting the even-numbered switches SW into the on state. Accordingly, the microcontroller 20 may wait for 1 second (step S205).

Thereafter, in the first step S206 (FIG. 3A), the diagnosis processor 22 may put the odd-numbered switches SW (the switches SW1 and SW3) into the on state in a short period starting from a timing t12. In this example, because the disconnection has occurred in the cell tab CT0, when the switch SW1 is put into the on state, for example, the voltage of the node N0 may change toward the voltage of the node N1; thus, the cell voltage VC1 may become smaller (part (D) of FIG. 9) and the cell voltage VC0 may become larger (part (E) of FIG. 9). Further, when the switch SW1 is put into the off state, the voltage of the node N0 may slowly change toward the original voltage. This may cause the cell voltages VC0 and VC1 to slowly change toward the original voltages. Further, the microcontroller 20 may wait for 1 second (step S209).

Thereafter, in the second step S202, the diagnosis processor 22 may put the even-numbered switches SW (the switches SW0, SW2, and SW4) into the on state in a short period starting from a timing t13. This operation may be substantially similar to the operation at the timing t11. Further, the microcontroller 20 may wait for 1 second (step S205).

Thereafter, in the second step S206, the diagnosis processor 22 may put the odd-numbered switches SW (the switches SW1 and SW3) into the on state in a short period starting from a timing t14. This operation may be substantially similar to the operation at the timing t12. Further, the microcontroller 20 may wait for 1 second (step S209).

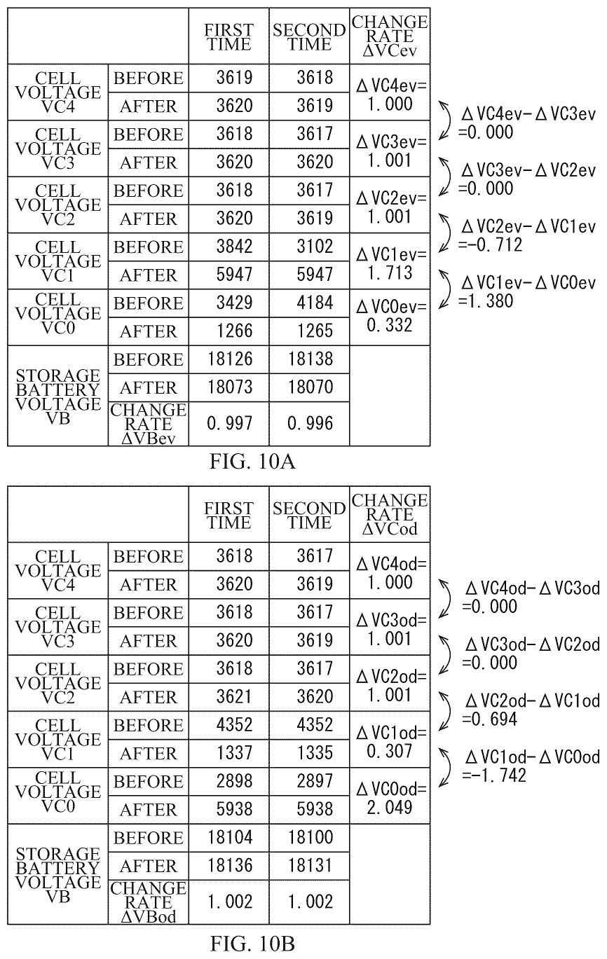

FIG. 10A illustrates an example of the cell voltages VC0 to VC4 and the storage battery voltage VB when the even-numbered switches SW are put into the on state. FIG. 10B illustrates an example of the cell voltages VC0 to VC4 and the storage battery voltage VB when the odd-numbered switches SW are put into the on state.

In this example, as illustrated in FIG. 10A, the change rate ΔVBev of the storage battery voltage VB for the first time and the change rate ΔVBev of the storage battery voltage VB for the second time, resulting from operating the even-numbered switches SW, may be greater than 0.9 and less than 1.1. In addition, as illustrated in FIG. 10B, the change rate ΔVBod of the storage battery voltage VB for the first time and the change rate ΔVBod of the storage battery voltage VB for the second time, resulting from operating the odd-numbered switches SW, may be greater than 0.9 and less than 1.1. Accordingly, the diagnosis processor 22 may determine that there is no influence of noise from the outside of the battery pack 1 and it is possible to perform the disconnection diagnosis based on the detection result of the cell voltages VC0 to VC4.

Further, in the disconnection determination process B1 (FIGS. 4A and 4B), the diagnosis processor 22 may check whether the change rates ΔVC0ev, ΔVC1ev, ΔVC2ev, ΔVC3ev, and ΔVC4ev of the cell voltages VC0 to VC4 resulting from operating the even-numbered switches SW, and the change rates ΔVC0od, ΔVC1od, ΔVC2od, ΔVC3od, and ΔVC4od of the cell voltages VC0 to VC4 resulting from operating the odd-numbered switches SW satisfy the conditions in steps S301, S304, S307, and S310.

In this example, the condition in step S301 may be satisfied, as illustrated in FIGS. 10A and 10B. In other words, “ΔVC1ev−ΔVC0ev>0.9” may be satisfied, and “ΔVC1od−ΔVC0od<−0.9” may be satisfied. Accordingly, in step S303, the diagnosis processor 22 may determine that the path leading from the battery cell BC to the voltage detector 21 via the cell tab CT0 is disconnected.

Thus having determined that the disconnection has occurred (“Y” in step S110 in FIG. 2A), the diagnosis processor 22 may re-confirm that the disconnection has occurred, with a higher accuracy.

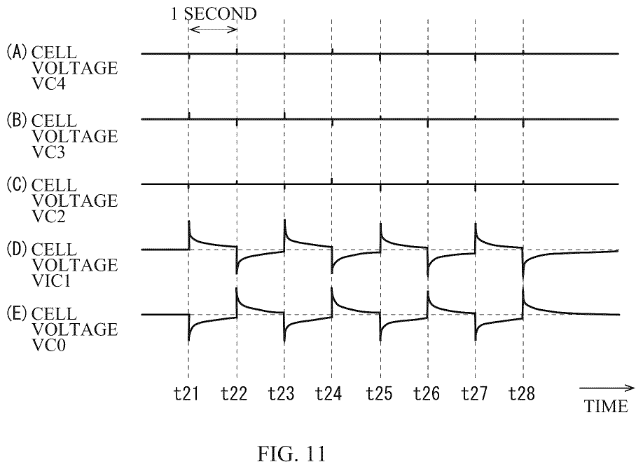

FIG. 11 illustrates results of the voltage measurement A2 in the battery pack 1 illustrated in FIG. 8. In FIG. 11, part (A) illustrates the waveform of the cell voltage VC4, part (B) illustrates the waveform of the cell voltage VC3, part (C) illustrates the waveform of the cell voltage VC2, part (D) illustrates the waveform of the cell voltage VC1, and part (E) illustrates the waveform of the cell voltage VC0.

In the first step S202 (FIG. 3A), the diagnosis processor 22 may put the even-numbered switches SW (the switches SW0, SW2, and SW4) into the on state in a short period starting from a timing t21. This operation may be substantially similar to the operation at the timing t11 in the voltage measurement A1 (FIG. 9). Further, the microcontroller 20 may wait for 1 second (step S205).

Next, in the first step S206 (FIG. 3A), the diagnosis processor 22 may put the odd-numbered switches SW (the switches SW1 and SW3) into the on state in a short period starting from a timing t22. This operation may be substantially similar to the operation at the timing t12 in the voltage measurement A1 (FIG. 9). Further, the microcontroller 20 may wait for 1 second (step S209).

The operations at subsequent timings t23 to t28 may be similar. In this example, the operations of step S202 for four times and the operations of step S206 for four times may be performed alternately.

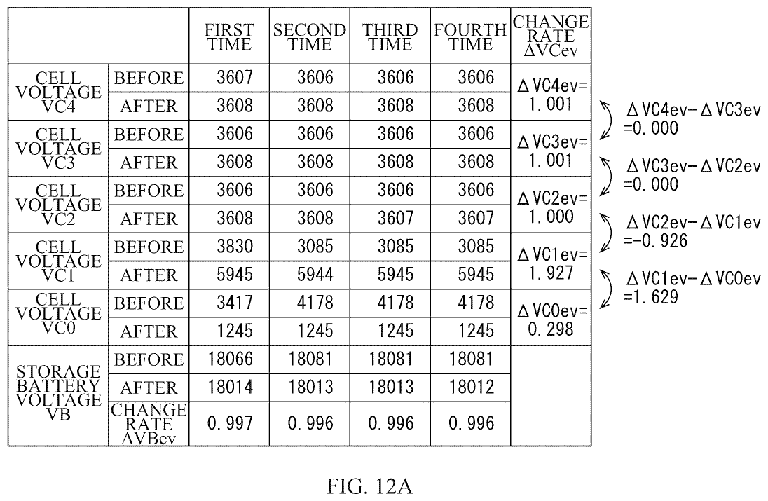

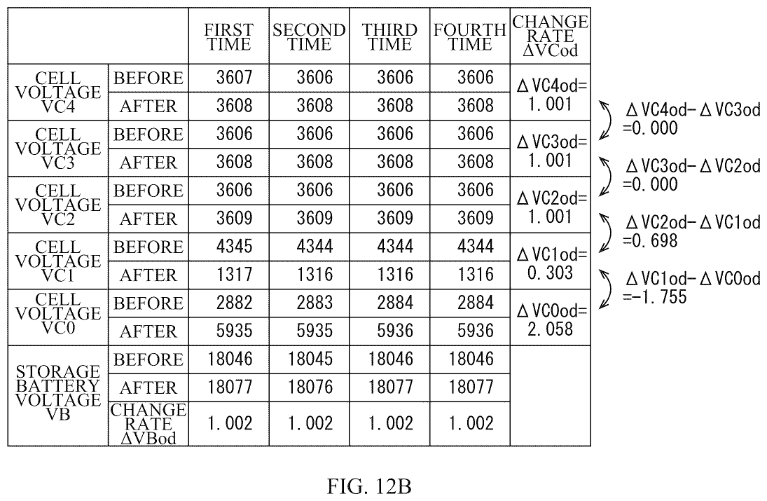

FIG. 12A illustrates an example of the cell voltages VC0 to VC4 and the storage battery voltage VB when the even-numbered switches SW are put into the on state. FIG. 12B illustrates an example of the cell voltages VC0 to VC4 and the storage battery voltage VB when the odd-numbered switches SW are put into the on state.

In this example, as illustrated in FIG. 12A, each of the change rates ΔVBev of the storage battery voltages VB for the four times, resulting from operating the even-numbered switches SW, may be greater than 0.9 and less than 1.1. In addition, as illustrated in FIG. 12B, each of the change rates ΔVBod of the storage battery voltages VB for the four times, resulting from operating the odd-numbered switches SW, may be greater than 0.9 and less than 1.1. Accordingly, the diagnosis processor 22 may determine that there is no influence of noise from the outside of the battery pack 1 and it is possible to perform the disconnection diagnosis based on the detection result of the cell voltages VC0 to VC4.

Further, in the disconnection determination process B2, the diagnosis processor 22 may check whether the change rates ΔVC0ev, ΔVC1ev, ΔVC2ev, ΔVC3ev, and ΔVC4ev of the cell voltages VC0 to VC4 resulting from operating the even-numbered switches SW, and the change rates ΔVC0od, ΔVC1od, ΔVC2od, ΔVC3od, and ΔVC4od of the cell voltages VC0 to VC4 resulting from operating the odd-numbered switches SW satisfy the conditions in steps S301, S304, S307, and S310.

In this example, the condition in step S301 may be satisfied, as illustrated in FIGS. 12A and 12B. In other words, “ΔVC1ev−ΔVC0ev>0.9” may be satisfied, and “ΔVC1od−ΔVC0od<−0.9” may be satisfied. Accordingly, in step S303, the diagnosis processor 22 may determine that the path leading from the battery cell BC to the voltage detector 21 via the cell tab CT0 is disconnected.

In this manner, the diagnosis processor 22 may identify the disconnection location W, as illustrated in FIG. 8.

As described above, the battery pack 1 includes the storage battery 11, the multiple switches SW, the voltage detection circuit (the voltage detector 21), and the diagnosis circuit (the diagnosis processor 22). The storage battery 11 includes the multiple battery cells BC coupled in series. The switches SW correspond to the respective battery cells BC and are each provided in a first parallel path of corresponding one of the battery cells BC. The voltage detection circuit (the voltage detector 21) is configured to detect respective voltages across the switches SW, as the multiple cell voltages VC corresponding to the respective battery cells BC. The diagnosis circuit (the diagnosis processor 22) is configured to put one or more (e.g., the even-numbered switches SW0, SW2, and SW4) of the switches SW into the on state in the predetermined period, and configured to perform the diagnosis process based on a detection result of the voltage detection circuit (the voltage detector 21) before the predetermined period and a detection result of the voltage detection circuit (the voltage detector 21) after the predetermined period. Thus, in the battery pack 1, for example, it is possible to diagnose whether a disconnection has occurred in the paths leading from the battery cells BC to the voltage detector 21 via the cell tabs CT0 to CT3, which helps to diagnose whether a malfunction has occurred.

For example, in the battery pack 1, the diagnosis process is performed based on the detection results of the voltage detection circuit (the voltage detector 21) before the predetermined period and after the predetermined period. Thus, for example, it is possible to shorten a diagnosis time, as compared with when performing the diagnosis process based on the detection result of the voltage detector 21 in the period of putting the switch SW into the on state. In other words, when detecting the voltage in the period of putting the switch SW into the on state, for example, the time length of the period of putting the switch SW into the on state is to be lengthened to some extent in order to perform AD conversion more reliably. In addition, when the period of putting the switch SW into the on state is thus lengthened, it takes a longer time until the voltage is stabilized after the switch SW is turned from the on state to the off state. This results in a longer diagnosis time. In contrast, in the battery pack 1, the voltage is detected in periods before and after the period of putting the switch SW into the on state. Thus, the battery pack 1 makes it possible to shorten the period of putting the switch SW into the on state, and to shorten the time until the voltage is stabilized after the switch SW is turned from the on state to the off state. This helps the battery pack 1 to effectively diagnose whether a malfunction has occurred in a short time.

In some embodiments, two adjacent ones of the battery cells BC may be coupled to each other via the coupling node. The diagnosis circuit (the diagnosis processor 22) may be configured to, in the diagnosis process, diagnose a disconnection of the path leading from the coupling node to the voltage detection circuit (the voltage detector 21). Thus, when a disconnection occurs in any of the cell tabs CT0 to CT3, it is possible to diagnose the disconnection. In other words, when a disconnection occurs in the cell tab CT4 or when a disconnection occurs in the cell tab CTG, for example, it is easy to diagnose the disconnection because the battery pack 1 becomes unable to perform charging and discharging. However, when a disconnection occurs in any one of the cell tabs CT0 to CT3, it is difficult to diagnose the disconnection because the battery pack 1 is able to perform charging and discharging. In addition, when a disconnection occurs in the cell tab CT0, for example, the voltage of the node N0 can become a voltage between the voltage of the node NG and the voltage of the node N1 because of the capacitors C0 and C1. Accordingly, when a disconnection occurs in any of the cell tabs CT0 to CT3, it is difficult to diagnose the disconnection. In the battery pack 1, one or more of the switches SW are put into the on state in the predetermined period, and the diagnosis process is performed based on the detection results of the voltage detection circuit before the predetermined period and after the predetermined period, which makes it possible to diagnose the disconnection of the cell tabs CT0 to CT3. This helps the battery pack 1 to diagnose whether a malfunction has occurred.

In some embodiments, the voltage detection circuit (the voltage detector 21) may be configured to detect the storage battery voltage VB of the storage battery 11. The diagnosis circuit (the diagnosis processor 22) may be configured to perform the diagnosis process further based on the storage battery voltage VB before the predetermined period and the storage battery voltage VB after the predetermined period. Thus, the battery pack 1 makes it possible to check whether there is an influence of noise from the outside of the battery pack 1, for example, which helps to increase the accuracy of the diagnosis process.

In some embodiments, the battery pack 1 may further include the multiple capacitors C0 to C4 corresponding to the respective battery cells BC and each provided in a second parallel path of corresponding one of the battery cells BC. Thus, the battery pack 1 makes it possible to stabilize the cell voltages VC0 to VC4, which makes it easier for the voltage detector 21 to detect the cell voltages VC0 to VC4, for example.

In some embodiments, the diagnosis circuit (the diagnosis processor 22) may be configured to put one or more even-numbered switches SW out of the switches SW into the on state in the first predetermined period, and put one or more odd-numbered switches SW out of the switches SW into the on state in the second predetermined period. Further, the diagnosis circuit (the diagnosis processor 22) may be configured to perform the diagnosis process based on the cell voltages VC before the first predetermined period, the cell voltages VC after the first predetermined period, the cell voltages VC before the second predetermined period, and the cell voltages VC after the second predetermined period. This helps the battery pack 1 to effectively perform the diagnosis process in a short time. In other words, when the diagnosis circuit sequentially selects one of the switches SW and puts the selected switch SW into the on state, for example, the diagnosis process takes time. In contrast, in the battery pack 1, one or more even-numbered switches SW out of the switches SW may be put into the on state in the first predetermined period, and one or more odd-numbered switches SW out of the switches SW may be put into the on state in the second predetermined period. Thus, the battery pack 1 makes it possible to reduce the number of periods of putting the switches SW into the on state, which helps to effectively perform the diagnosis process in a short time.

In some embodiments, the diagnosis circuit (the diagnosis processor 22) may be configured to: calculate the respective first change rates (the change rates ΔVCev) of the cell voltages VC between before and after the first predetermined period, and perform the diagnosis process based on a difference between the first change rates (the change rates ΔVCev) of two of the cell voltages VC corresponding to two adjacent ones of the battery cells BC; and calculate the respective second change rates (the change rates ΔVCod) of the cell voltages VC between before and after the second predetermined period, and perform the diagnosis process based on a difference between the second change rates (the change rates ΔVCod) of two of the cell voltages VC corresponding to two adjacent ones of the battery cells BC. Thus, the battery pack 1 makes it possible to identify the location where the disconnection has occurred, as illustrated in FIGS. 4A and 4B, which helps to effectively perform the diagnosis process.

In some embodiments, the diagnosis circuit (the diagnosis processor 22) may be configured to: change the time length of a waiting time after the first predetermined period, depending on whether the amount of change in one or more of the cell voltages VC between before and after the first predetermined period exceeds a predetermined amount; and change the time length of a waiting time after the second predetermined period, depending on whether the amount of change in one or more of the cell voltages VC between before and after the second predetermined period exceeds a predetermined amount. For example, when the amount of voltage change in one or more of the cell voltages VC0 to VC4 exceeds ±1 V, there is a possibility that a disconnection has occurred. Accordingly, in this case, the microcontroller 20 may wait for 1 second in order to provide time until the voltage returns to the original voltage to some extent. In contrast, when the amount of voltage change in each of the cell voltages VC0 to VC4 is within ±1 V, it is unlikely that a disconnection has occurred. Accordingly, in this case, the microcontroller 20 may wait for 0.25 seconds in order to shorten the time taken for the disconnection diagnosis process. This helps the battery pack 1 to effectively perform the diagnosis process.

As described above, in the present example embodiment, the battery pack includes the storage battery, the multiple switches, the voltage detection circuit, and the diagnosis circuit. The storage battery includes the multiple battery cells coupled in series. The switches correspond to the respective battery cells and are each provided in the first parallel path of corresponding one of the battery cells. The voltage detection circuit is configured to detect respective voltages across the switches, as the multiple cell voltages corresponding to the respective battery cells. The diagnosis circuit is configured to put one or more of the switches into the on state in the predetermined period, and configured to perform the diagnosis process based on a detection result of the voltage detection circuit before the predetermined period and a detection result of the voltage detection circuit after the predetermined period. This helps to diagnose whether a malfunction has occurred.

In some embodiments, two adjacent ones of the battery cells may be coupled to each other via the coupling node. The diagnosis circuit may be configured to, in the diagnosis process, diagnose a disconnection of the path leading from the coupling node to the voltage detection circuit. This helps to diagnose whether a malfunction has occurred.

In some embodiments, the voltage detection circuit may be configured to detect the storage battery voltage of the storage battery. The diagnosis circuit may be configured to perform the diagnosis process further based on the storage battery voltage before the predetermined period and the storage battery voltage after the predetermined period. This helps to increase the accuracy of the diagnosis process.

In some embodiments, the diagnosis circuit may be configured to put one or more even-numbered switches out of the switches into the on state in the first predetermined period, and put one or more odd-numbered switches out of the switches into the on state in the second predetermined period. Further, the diagnosis circuit may be configured to perform the diagnosis process based on the cell voltages before the first predetermined period, the cell voltages after the first predetermined period, the cell voltages before the second predetermined period, and the cell voltages after the second predetermined period. This helps to effectively perform the diagnosis process in a short time.

In some embodiments, the diagnosis circuit may be configured to: calculate the respective first change rates of the cell voltages between before and after the first predetermined period, and perform the diagnosis process based on a difference between the first change rates of two of the cell voltages corresponding to two adjacent ones of the battery cells; and calculate the respective second change rates of the cell voltages between before and after the second predetermined period, and perform the diagnosis process based on a difference between the second change rates of two of the cell voltages corresponding to two adjacent ones of the battery cells. This helps to effectively perform the diagnosis process.

In some embodiments, the diagnosis circuit may be configured to: change the time length of the waiting time after the first predetermined period, depending on whether the amount of change in one or more of the cell voltages between before and after the first predetermined period exceeds the predetermined amount; and change the time length of the waiting time after the second predetermined period, depending on whether the amount of change in one or more of the cell voltages between before and after the second predetermined period exceeds the predetermined amount. This helps to effectively perform the diagnosis process.

Although the present disclosure has been described hereinabove with reference to some embodiments and modification examples, a configuration of any embodiment of the present disclosure is not limited to the configurations described in relation to the example embodiments and modification examples, and is therefore modifiable in a variety of ways.

For example, in the foregoing example embodiment, the five cell blocks CBL0 to BCL4 may be provided, but the number of the cell blocks CBL is not limited to five. In some embodiments, the number of the cell blocks CBL may be greater than or equal to two and less than or equal to four, or greater than or equal to six, for example.

For example, in the foregoing example embodiment, the cell block CBL may include two battery cells BC coupled in parallel, but this is non-limiting. In some embodiments, the cell block CBL may include one battery cell BC or include three or more battery cells BC, for example.

For example, in the foregoing example embodiment, the capacitors C0 to C4 may be included, but this is non-limiting. In some embodiments, the capacitors C0 to C4 may be omitted.

For example, in the foregoing example embodiment, in the period in which the charging is being performed, the disconnection diagnosis may be performed by temporarily stopping the charging, but this is non-limiting. The disconnection diagnosis may be performed in various cases. In some embodiments, when the battery pack 1 is stored in a state of being detached from the equipment, for example, the battery pack 1 may intermittently start up from a power save state and perform the disconnection diagnosis.

For example, in the foregoing example embodiment, various numerical values, including the cell voltage VC, the storage battery voltage VB, the waiting time of the measurement, and thresholds, are examples, and may be changed as appropriate.

The effects described herein are mere examples, and effects of an embodiment of the present disclosure are therefore not limited to those described herein. Accordingly, an embodiment of the present disclosure may achieve any other effect.

Furthermore, the present disclosure encompasses any possible combination of some or all of the various embodiments and the modification examples described herein and incorporated herein. It is possible to achieve at least the following configurations from the above-described example embodiments of the present disclosure.

<1> A battery pack including:
a storage battery including multiple battery cells coupled in series;
multiple switches corresponding to the respective battery cells and each provided in a first parallel path of corresponding one of the battery cells;
a voltage detection circuit configured to detect respective voltages across the switches, as multiple cell voltages corresponding to the respective battery cells; and
a diagnosis circuit configured to put one or more of the switches into an on state in a predetermined period, and configured to perform a diagnosis process based on a detection result of the voltage detection circuit before the predetermined period and a detection result of the voltage detection circuit after the predetermined period.

<2> The battery pack according to <1>, in which
two adjacent ones of the battery cells are coupled to each other via a coupling node, and
the diagnosis circuit is configured to, in the diagnosis process, diagnose a disconnection of a path leading from the coupling node to the voltage detection circuit.

<3> The battery pack according to <1> or <2>, in which
the voltage detection circuit is configured to detect a storage battery voltage of the storage battery, and
the diagnosis circuit is configured to perform the diagnosis process further based on the storage battery voltage before the predetermined period and the storage battery voltage after the predetermined period.

<4> The battery pack according to any one of <1> to <3>, further including
multiple capacitors corresponding to the respective battery cells and each provided in a second parallel path of corresponding one of the battery cells.

<5> The battery pack according to any one of <1> to <4>, in which
the predetermined period includes a first predetermined period and a second predetermined period, and
the diagnosis circuit is configured to
   put one or more even-numbered switches out of the switches into the on state in the first predetermined period,
   put one or more odd-numbered switches out of the switches into the on state in the second predetermined period, and
   perform the diagnosis process based on the cell voltages before the first predetermined period, the cell voltages after the first predetermined period, the cell voltages before the second predetermined period, and the cell voltages after the second predetermined period.

<6> The battery pack according to <5>, in which the diagnosis circuit is configured to
calculate respective first change rates of the cell voltages between before and after the first predetermined period, and perform the diagnosis process based on a difference between the first change rates of two of the cell voltages corresponding to two adjacent ones of the battery cells, and
calculate respective second change rates of the cell voltages between before and after the second predetermined period, and perform the diagnosis process based on a difference between the second change rates of two of the cell voltages corresponding to two adjacent ones of the battery cells.

<7> The battery pack according to <5>, in which the diagnosis circuit is configured to
change a time length of a waiting time after the first predetermined period, depending on whether an amount of change in one or more of the cell voltages between before and after the first predetermined period exceeds a predetermined amount, and
change a time length of a waiting time after the second predetermined period, depending on whether an amount of change in one or more of the cell voltages between before and after the second predetermined period exceeds a predetermined amount.

<8> The battery pack according to any one of <1> to <7>, further including:
a first terminal led to one end of the storage battery;
a second terminal led to another end of the storage battery; and
a cut-off switch provided in a charge and discharge path of the storage battery, the charge and discharge path coupling the first terminal and the second terminal to each other, in which
the diagnosis circuit is configured to fix the cut-off switch in an off state, based on a result of the diagnosis process.

<9> A diagnosis method including:
detecting, in a battery pack including multiple battery cells and multiple switches, respective voltages across the switches, as multiple first cell voltages corresponding to the respective battery cells, the battery cells being coupled in series, the switches corresponding to the respective battery cells and each being provided in a first parallel path of corresponding one of the battery cells;
putting one or more of the switches into an on state in a predetermined period;
detecting respective voltages across the switches after the predetermined period, as multiple second cell voltages corresponding to the respective battery cells; and
performing a diagnosis process based on the first cell voltages and the second cell voltages.

A battery pack according to at least one example embodiment of the present disclosure and a diagnosis method according to at least one example embodiment of the present disclosure each help to diagnose whether a malfunction has occurred.

Although the present disclosure has been described hereinabove in terms of the example embodiment and modification examples, the present disclosure is not limited thereto. It should be appreciated that variations may be made in the described example embodiment and modification examples by those skilled in the art without departing from the scope of the present disclosure as defined by the following claims.

The limitations in the claims are to be interpreted broadly based on the language employed in the claims and not limited to examples described in this specification or during the prosecution of the application, and the examples are to be construed as non-exclusive.

As used in this specification and the appended claims, the singular forms “a,” “an,” and “the” include, especially in the context of the claims, are to be construed to cover both the singular and the plural, unless otherwise indicated herein or clearly contradicted by context.

Throughout this specification and the appended claims, unless the context requires otherwise, the terms “comprise”, “include”, “have”, and their variations are to be construed to cover the inclusion of a stated element, integer, or step but not the exclusion of any other non-stated element, integer, or step.

The use of the terms first, second, etc. do not denote any order or importance, but rather the terms first, second, etc. are used to distinguish one element from another.

The term “substantially”, “approximately”, “about”, and its variants having the similar meaning thereto are defined as being largely but not necessarily wholly what is specified as understood by one of ordinary skill in the art.

The term “disposed on/provided on/formed on” and its variants having the similar meaning thereto as used herein refer to elements disposed directly in contact with each other or indirectly by having intervening structures therebetween.

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A battery pack comprising:
a storage battery including multiple battery cells coupled in series;
multiple switches corresponding to the respective battery cells and each provided in a first parallel path of corresponding one of the battery cells;
a voltage detection circuit configured to detect respective voltages across the switches, as multiple cell voltages corresponding to the respective battery cells; and
a diagnosis circuit configured to put one or more of the switches into an on state in a predetermined period, and configured to perform a diagnosis process based on a detection result of the voltage detection circuit before the predetermined period and a detection result of the voltage detection circuit after the predetermined period.

2. The battery pack according to claim 1, wherein
two adjacent ones of the battery cells are coupled to each other via a coupling node, and
the diagnosis circuit is configured to, in the diagnosis process, diagnose a disconnection of a path leading from the coupling node to the voltage detection circuit.

3. The battery pack according to claim 1, wherein
the voltage detection circuit is configured to detect a storage battery voltage of the storage battery, and
the diagnosis circuit is configured to perform the diagnosis process further based on the storage battery voltage before the predetermined period and the storage battery voltage after the predetermined period.

4. The battery pack according to claim 1, further comprising
multiple capacitors corresponding to the respective battery cells and each provided in a second parallel path of corresponding one of the battery cells.

5. The battery pack according to claim 1, wherein
the predetermined period includes a first predetermined period and a second predetermined period, and
the diagnosis circuit is configured to
put one or more even-numbered switches out of the switches into the on state in the first predetermined period,
put one or more odd-numbered switches out of the switches into the on state in the second predetermined period, and
perform the diagnosis process based on the cell voltages before the first predetermined period, the cell voltages after the first predetermined period, the cell voltages before the second predetermined period, and the cell voltages after the second predetermined period.

6. The battery pack according to claim 5, wherein the diagnosis circuit is configured to
calculate respective first change rates of the cell voltages between before and after the first predetermined period, and perform the diagnosis process based on a difference between the first change rates of two of the cell voltages corresponding to two adjacent ones of the battery cells, and
calculate respective second change rates of the cell voltages between before and after the second predetermined period, and perform the diagnosis process based on a difference between the second change rates of two of the cell voltages corresponding to two adjacent ones of the battery cells.

7. The battery pack according to claim 5, wherein the diagnosis circuit is configured to
change a time length of a waiting time after the first predetermined period, depending on whether an amount of change in one or more of the cell voltages between before and after the first predetermined period exceeds a predetermined amount, and
change a time length of a waiting time after the second predetermined period, depending on whether an amount of change in one or more of the cell voltages between before and after the second predetermined period exceeds a predetermined amount.

8. The battery pack according to claim 1, further comprising:
a first terminal led to one end of the storage battery;
a second terminal led to another end of the storage battery; and
a cut-off switch provided in a charge and discharge path of the storage battery, the charge and discharge path coupling the first terminal and the second terminal to each other, wherein
the diagnosis circuit is configured to fix the cut-off switch in an off state, based on a result of the diagnosis process.

9. A diagnosis method comprising:
detecting, in a battery pack including multiple battery cells and multiple switches, respective voltages across the switches, as multiple first cell voltages corresponding to the respective battery cells, the battery cells being coupled in series, the switches corresponding to the respective battery cells and each being provided in a first parallel path of corresponding one of the battery cells;
putting one or more of the switches into an on state in a predetermined period;
detecting respective voltages across the switches after the predetermined period, as multiple second cell voltages corresponding to the respective battery cells; and
performing a diagnosis process based on the first cell voltages and the second cell voltages.
